(19) United States
(12) Patent Application Publication
(10) Pub. No.: US 2025/0188301 A1
(43) Pub. Date: Jun. 12, 2025

(54) IMPROVED CONDUCTIVE INK COMPOSITIONS

(71) Applicant: ELECTRONINKS INCORPORATED, Austin, TX (US)

(72) Inventors: S. Brett WALKER, Austin, TX (US); Melburne LEMIEUX, El Dorado Hills, CA (US); K.L. Iresha Sampathi PERERA, Austin, TX (US); Garret MCKERRICHER, Austin, TX (US); Ron CHERTAKOVSKY, Austin, TX (US); Scott Soung Jae LEE, Austin, TX (US)

(73) Assignee: ELECTRONINKS INCORPORATED, Austin, TX (US)

(21) Appl. No.: 18/843,863

(22) PCT Filed: Mar. 5, 2023
(86) PCT No.: PCT/US2023/063747

§ 371 Date: Sep. 4, 2024

(51) Int. Cl. C09D 11/52; C09D 11/322

(52) U.S. Cl. CPC C09D 11/52; C09D 11/322

(57) ABSTRACT

Improved conductive ink compositions are provided. The improved conductive ink compositions include a silver complex formed by mixing a silver carboxy late, specifically a silver decanoate isomer, and at least one dissolving agent, in particular where the at least one dissolving agent comprises a terpene, a terpenoid; or a combination thereof. The silver carboxy late of the subject ink compositions is decarboxylated at a temperature of 250° C. or less, optionally in the presence of an adhesion promoter and/or an acid stabilizer, to form a conductive structure. Methods of making conductive structures, including methods wherein the disclosed compositions are applied to a substrate by various techniques, are also provided.

### CROSS-REFERENCE TO RELATED APPLICATIONS

This application claims the benefit of U.S. Provisional Application No. 63/316,949, filed on Mar. 4, 2022, U.S. Provisional Application No. 63/370,343, filed on Aug. 3, 2022, and U.S. Provisional Application No. 63/384,202, filed on Nov. 17, 2022, the disclosures each of which are incorporated herein by reference in their entireties.

### FIELD OF THE INVENTION

The present disclosure relates generally to novel conductive ink compositions and their methods of preparation and use. More particularly, the present disclosure relates to improved particle-free ink compositions comprising silver carboxylates that form conductive structures at low temperature.

### BACKGROUND OF THE INVENTION

The electronics, display, and energy industries rely on the production and use of coatings and patterns of conductive materials to form circuits on organic and inorganic substrates. Printed electronics offer an attractive alternative to conventional technologies by enabling the creation of large-area, flexible devices at low cost. There is a great need for high-conductivity materials with fine-scale features in modern electronics such as solar cell electrodes, flexible displays, radio frequency identification tags, antennas, and many more. In efforts to make these high-technology devices increasingly affordable, the substrates used typically have relatively little temperature resilience and require low processing temperatures to maintain integrity.

The vast majority of commercially produced conductive inks are specifically designed for inkjet, screen-printing, or roll-to-roll processing methods in order to process large areas with fine-scale features in short time periods. These inks have disparate viscosities and synthesis parameters. Particle-based inks are based on conductive metal particles, which are typically synthesized separately and then incorporated into an ink formulation. The resulting ink is then tuned for specific particle process.

Typically, precursor-based inks are based on thermally unstable precursor complexes that undergo reduction to a conductive metal upon heating. Prior particle- and precursor-based methods generally rely on high temperatures to form conductive coatings and thus may not be compatible with substrates that require low processing temperatures to maintain integrity. For example, silver compounds with carbamate or other relatively low molecular weight ligands (compared to polymer stabilizers) have been synthesized that decompose at temperatures near 150° C., yielding electrical conductivities approaching that of bulk silver. Unfortunately, even these temperatures can render the ink incompatible with many plastic and paper substrates commonly used in flexible electronic and biomedical devices.

International Publication No. WO2015/160938 provides conductive ink compositions, methods of production and use, and conductive structures prepared using the ink compositions. Among the ink compositions are examples comprising a silver carboxylate, at least one dissolving agent, and a catalyst that decarboxylates the silver carboxylate to form a conductive structure. The decarboxylation reaction can occur at low temperatures.

European Patent No. EP 3597707 B1 provides conductive ink compositions for inkjet or screen printing processes. The conductive ink compositions comprise a silver carboxylate, a terpene, and at least one carboxylic acid as a further component. The ink compositions can be used in methods for producing a pattern on a substrate.

International Publication Nos. WO2015/192248 A1 and WO2018/146617 A1 provide conductive ink compositions containing a silver carboxylate, a solvent, and a polymer binder.

Despite these and other advances in the field, there continues to be a need for particle-free conductive ink compositions with improved properties. Therefore, it is an object of the present invention to provide improved, stable, particle-free conductive ink compositions and methods for their preparation and use, in particular compositions that can form conductive structures at low temperatures and ideally without catalysts. It is also an object of the present invention to provide improved, stable, particle-free conductive ink compositions and methods for their preparation and use, wherein the compositions have considerable adhesion to a variety of substrates for a variety of purposes. Such purposes can include those involving epoxy molding compound (EMC), solder resist functionality, silver nanowire substrates (SNW), and so forth, with both thin and thick inkjet printing layers. Such conductive inks can be used on a variety of substrates to form conductive structures with superior physical, mechanical, and electrical properties.

### SUMMARY OF THE INVENTION

The instant disclosure addresses these and other considerations by providing in one aspect a conductive ink composition comprising a silver complex formed by combining a silver decanoate and at least one dissolving agent, wherein the at least one dissolving agent comprises a terpene, a terpenoid, or a combination thereof, and wherein the silver decanoate is decarboxylated at a temperature of 250° C. or less to form a conductive structure.

In some embodiments, the silver decanoate comprises at least one α-branched silver decanoate isomer. In some embodiments, the silver decanoate comprises a plurality of α-branched silver decanoate isomers.

In some embodiments, the silver decanoate has a structure:

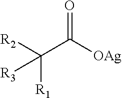

wherein R₁ and R₂ is each independently an alkyl group, wherein R₃ is either hydrogen or an alkyl group, and wherein R₁, R₂, and R₃ together comprise eight total carbon atoms. In more specific embodiments, R₁ and R₂ is each independently methyl or ethyl. In other more specific embodiments, the silver decanoate comprises silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or a combination thereof.

In some embodiments, the conductive ink composition is particle free.

In some embodiments, the terpene is a purified terpene or the terpenoid is a purified terpenoid.

In some embodiments, the terpene is a pinene or a limonene.

In some embodiments, the terpenoid is a terpineol.

In some embodiments, the at least one dissolving agent comprises a limonene and a terpineol, and more specifically, the limonene is a purified limonene and the terpineol is a purified terpineol.

In some embodiments, the composition further comprises an adhesion promoter. In specific embodiments, the adhesion promoter comprises a reactive silane, more specifically, the adhesion promoter comprises an alkoxysilane, and even more specifically, the adhesion promoter comprises an ethoxysilyl modified polyalkene. In some specific embodiments, the adhesion promoter comprises a triethoxysilyl modified poly-1,2-butadiene.

In other specific embodiments, the adhesion promoter comprises a dendrimeric compound, more specifically a poly(amidoamine) dendrimeric compound, and even more specifically a generation 2 poly(amidoamine) dendrimeric compound or a hydrophobe substituted poly(amidoamine) dendrimeric compound, such as a C12 hydrophobe.

In some embodiments, the composition further comprises an acid stabilizer, specifically wherein the acid stabilizer is a C₆₋₁₂ α-branched alkanoic acid, more specifically wherein the acid stabilizer is an α-branched decanoic acid isomer, and even more specifically wherein the acid stabilizer is 2,2-dimethylhexanoic acid or 2,2-dimethylnonanoic acid.

In some embodiments, the silver decanoate comprises at least one α-branched silver decanoate isomer, the at least one dissolving agent comprises a limonene and a terpineol, and the conductive ink composition further comprises an adhesion promoter comprising a reactive silane. In specific embodiments, the composition further comprises an acid stabilizer.

In some embodiments, the silver decanoate comprises at least one α-branched silver decanoate isomer, the at least one dissolving agent comprises a limonene, and the conductive ink composition further comprises an acid stabilizer.

In some embodiments, the conductive ink composition has a concentration of about 1 to about 50 weight percent silver decanoate.

In some embodiments, the conductive ink composition has a viscosity from about 5 centipoise to about 50 centipoise.

In some embodiments, the conductive ink composition has a viscosity from about 50 centipoise to about 1000 centipoise.

In some embodiments, the conductive structure has a resistance of no more than 5 ohms per square, no more than 2 ohms per square, no more than 1 ohm per square, or no more than 0.5 ohms per square.

In some embodiments, the conductive structure has a bulk silver content of at least 1%.

In some embodiments, the silver decanoate is decarboxylated at a temperature of 180° C. or less to form a conductive structure.

In some embodiments, the silver decanoate is decarboxylated at a temperature of 150° C. or less to form a conductive structure.

In another aspect is provided a method of making a conductive ink composition, comprising:
dissolving a silver decanoate in at least one dissolving agent to form a conductive ink composition;
wherein the silver decanoate comprises at least one α-branched silver decanoate isomer and the at least one dissolving agent comprises a terpene, a terpenoid; or a combination thereof.

In some embodiments, the silver decanoate does not comprise silver n-decanoate.

In some embodiments, the conductive ink composition does not comprise a catalyst. More specifically, in some embodiments, the conductive ink composition does not comprise a catalyst comprising an amine.

In some embodiments, the conductive ink composition is particle-free.

In some embodiments, the silver decanoate comprises a plurality of α-branched silver decanoate isomers.

In some embodiments, the silver decanoate has a structure:

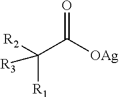

wherein R₁ and R₂ is each independently an alkyl group, wherein R₃ is either hydrogen or an alkyl group, and wherein R₁, R₂, and R₃ together comprise eight total carbon atoms.

In some specific embodiments, R₁ and R₂ is each independently methyl or ethyl. In some specific embodiments, the silver decanoate comprises silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or a combination thereof.

In some embodiments, the terpene is a purified terpene or the terpenoid is a purified terpenoid.

In some embodiments, the terpene is a pinene or a limonene.

In some embodiments, the terpenoid is a terpineol.

In some embodiments, the at least one dissolving agent comprises a limonene and a terpineol. More specifically, the limonene is a purified limonene and the terpineol is a purified terpineol.

In some embodiments, the method comprises the further step of dissolving an adhesion promoter in the at least one dissolving agent. Specifically, the adhesion promoter can comprise a reactive silane, more specifically an alkoxysilane, even more specifically an ethoxysilyl modified polyalkene, and even more specifically a triethoxysilyl modified poly-1,2-butadiene. In other specific embodiments, the adhesion promoter can comprise a dendrimeric compound, more specifically a poly(amidoamine) dendrimeric compound, and even more specifically a generation 2 poly(amidoamine) dendrimeric compound or a hydrophobe substituted poly(amidoamine) dendrimeric compound, such as a C12 hydrophobe.

In some embodiments, the method comprises the further step of dissolving an acid stabilizer in the at least one dissolving agent. Specifically, the acid stabilizer is a C₆₋₁₂ α-branched alkanoic acid, more specifically the acid stabilizer is an α-branched decanoic acid isomer, and even more specifically the acid stabilizer is 2,2-dimethylhexanoic acid or 2,2-dimethylnonanoic acid.

In some embodiments, the silver decanoate comprises at least one α-branched silver decanoate isomer, the at least one dissolving agent comprises a limonene and a terpineol, and the method comprises a further step of dissolving an adhesion promoter comprising a reactive silane in the dissolving agent and more specifically the further step of dissolving an acid stabilizer in the dissolving agent.

In some embodiments, the silver decanoate comprises at least one α-branched silver decanoate isomer, the at least one dissolving agent comprises a limonene, and the method comprises a further step of dissolving an acid stabilizer in the dissolving agent.

In some embodiments, the conductive ink composition has a concentration of about 1 to about 50 weight percent silver decanoate.

In some embodiments, the conductive ink composition has a viscosity from about 5 centipoise to about 50 centipoise.

In some embodiments, the conductive ink composition has a viscosity from about 50 centipoise to about 1000 centipoise.

In some embodiments, the silver decanoate is decarboxylated at a temperature of 180° C. or less to form a conductive structure.

In some embodiments, the silver decanoate is decarboxylated at a temperature of 150° C. or less to form a conductive structure.

In another aspect is provided a method of forming a conductive structure, comprising:
applying any of the above-describe conductive ink compositions to a substrate; and
heating the conductive ink composition on the substrate to a temperature of about 250° C. or less to form the conductive structure.

In still another aspect, the techniques described herein relate to a conductive ink composition including a silver complex formed by combining: a silver decanoate; at least one dissolving agent; and an adhesion promoter including a reactive silane or an epoxide; wherein the silver decanoate is decarboxylated at a temperature of 250° C. or less to form a conductive structure.

In some embodiments, the techniques described herein relate to a conductive ink composition, wherein the silver decanoate includes at least one α-branched silver decanoate isomer.

In some embodiments, the techniques described herein relate to a conductive ink composition, wherein the silver decanoate includes a plurality of α-branched silver decanoate isomers.

In some embodiments, the techniques described herein relate to a conductive ink composition, wherein the silver decanoate has a structure:

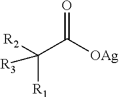

wherein R₁ and R₂ is each independently an alkyl group, wherein R₃ is either hydrogen or an alkyl group, and wherein R₁, R₂, and R₃ together include eight total carbon atoms.

In some embodiments, the techniques described herein relate to a conductive ink composition, wherein R₁ and R₂ is each independently methyl or ethyl.

In some embodiments, the techniques described herein relate to a conductive ink composition, wherein the silver decanoate includes silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or a combination thereof.

In some embodiments, the techniques described herein relate to a conductive ink composition, wherein the conductive ink composition is particle free.

In some embodiments, the techniques described herein relate to a conductive ink composition, wherein the at least one dissolving agent includes a terpene, a terpenoid, or a combination thereof.

In some embodiments, the techniques described herein relate to a conductive ink composition, wherein the terpene is a pinene or a limonene.

In some embodiments, the techniques described herein relate to a conductive ink composition, wherein the terpenoid is a terpineol.

In some embodiments, the techniques described herein relate to a conductive ink composition, wherein the at least one dissolving agent includes a limonene and a terpineol.

In some embodiments, the techniques described herein relate to a conductive ink composition, wherein the limonene is a purified limonene and the terpineol is a purified terpineol.

In some embodiments, the techniques described herein relate to a conductive ink composition, wherein the adhesion promoter includes a reactive silane and an epoxide.

In some embodiments, the techniques described herein relate to a conductive ink composition, wherein the adhesion promoter is a structure of formula I:

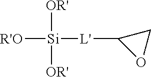

I, wherein each R′ is independently a C₁-C₆ alkyl group, and L′ is an alkyl linker group.

In some embodiments, the techniques described herein relate to a conductive ink composition, wherein each R′ is independently a methyl or an ethyl group.

In some embodiments, the techniques described herein relate to a conductive ink composition, wherein L′ is a C₂-C₁₀-alkyl linker group.

In some embodiments, the techniques described herein relate to a conductive ink composition, wherein L′ is a substituted C₂-C₁₀-alkyl linker group.

In some embodiments, the techniques described herein relate to a conductive ink composition, wherein one or more carbon atoms in L′ is be substituted with a heteroatom.

In some embodiments, the techniques described herein relate to a conductive ink composition, wherein the adhesion promoter is a structure of formula II:

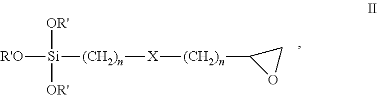

wherein each R′ is independently a methyl or an ethyl group, X is a heteroatom, and each n is independently 1-6.

In some embodiments, the techniques described herein relate to a conductive ink composition, wherein each R′ is a methyl group, X is oxygen, and each n is independently 1-3.

In some embodiments, the techniques described herein relate to a conductive ink composition, wherein the adhesion promoter is

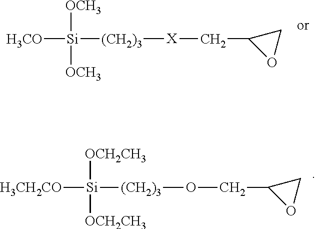

In some embodiments, the techniques described herein relate to a conductive ink composition, wherein the adhesion promoter includes an alkoxysilane.

In some embodiments, the techniques described herein relate to a conductive ink composition, wherein the adhesion promoter includes a methoxysilyl or an ethoxysilyl group.

In some embodiments, the techniques described herein relate to a conductive ink composition, wherein the adhesion promoter includes a dendrimeric compound, more specifically a poly(amidoamine) dendrimeric compound, and even more specifically a generation 2 poly(amidoamine) dendrimeric compound or a hydrophobe substituted poly(amidoamine) dendrimeric compound, such as a C12 hydrophobe.

In some embodiments, the techniques described herein relate to a conductive ink composition, further including an acid stabilizer.

In some embodiments, the techniques described herein relate to a conductive ink composition, wherein the acid stabilizer is a C₆₋₁₂ α-branched alkanoic acid.

In some embodiments, the techniques described herein relate to a conductive ink composition, wherein the acid stabilizer is an α-branched decanoic acid isomer.

In some embodiments, the techniques described herein relate to a conductive ink composition, wherein the acid stabilizer is 2,2-dimethylhexanoic acid or 2,2-dimethylnonanoic acid.

In some embodiments, the techniques described herein relate to a conductive ink composition, wherein the silver decanoate includes at least one α-branched silver decanoate isomer, the at least one dissolving agent includes a limonene and a terpineol, and the adhesion promoter includes a reactive silane and an epoxide.

In some embodiments, the techniques described herein relate to a conductive ink composition, further including an acid stabilizer.

In some embodiments, the techniques described herein relate to a conductive ink composition, wherein the silver decanoate includes at least one α-branched silver decanoate isomer, the at least one dissolving agent includes a limonene, and the conductive ink composition further includes an acid stabilizer.

In some embodiments, the techniques described herein relate to a conductive ink composition, wherein the conductive ink composition has a concentration of about 1 to about 50 weight percent silver decanoate.

In some embodiments, the techniques described herein relate to a conductive ink composition, wherein the conductive ink composition has a viscosity from about 5 centipoise to about 50 centipoise.

In some embodiments, the techniques described herein relate to a conductive ink composition, wherein the conductive structure has a resistance of no more than 5 ohms per square, no more than 2 ohms per square, no more than 1 ohm per square, or no more than 0.5 ohms per square.

In some embodiments, the techniques described herein relate to a conductive ink composition, wherein the conductive structure has a bulk silver content of at least 1%.

In some embodiments, the techniques described herein relate to a conductive ink composition, wherein the silver decanoate is decarboxylated at a temperature of 180° C. or less to form a conductive structure.

In some embodiments, the techniques described herein relate to a conductive ink composition, wherein the silver decanoate is decarboxylated at a temperature of 150° C. or less to form a conductive structure.

In another aspect, the techniques described herein relate to a method of making a conductive ink composition, including: dissolving a silver decanoate and an adhesion promoter in at least one dissolving agent to form a conductive ink composition; wherein the silver decanoate includes at least one α-branched silver decanoate isomer and wherein the adhesion promoter includes a reactive silane or an epoxide.

In some embodiments, the techniques described herein relate to a method, wherein the silver decanoate includes a plurality of α-branched silver decanoate isomers.

In some embodiments, the techniques described herein relate to a method, wherein the silver decanoate has a structure:

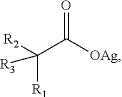

wherein R₁ and R₂ is each independently an alkyl group, wherein R₃ is either hydrogen or an alkyl group, and wherein R₁, R₂, and R₃ together include eight total carbon atoms.

In some embodiments, the techniques described herein relate to a method, wherein R₁ and R₂ is each independently methyl or ethyl.

In some embodiments, the techniques described herein relate to a method, wherein the silver decanoate includes silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or a combination thereof.

In some embodiments, the techniques described herein relate to a method, wherein the at least one dissolving agent includes a terpene or a terpenoid.

In some embodiments, the techniques described herein relate to a method, wherein the terpene is a pinene or a limonene.

In some embodiments, the techniques described herein relate to a method, wherein the terpenoid is a terpineol.

In some embodiments, the techniques described herein relate to a method, wherein the at least one dissolving agent includes a limonene or a terpineol.

In some embodiments, the techniques described herein relate to a method, wherein the limonene is a purified limonene and the terpineol is a purified terpineol.

In some embodiments, the techniques described herein relate to a method, wherein the adhesion promoter includes a reactive silane and an epoxide.

In some embodiments, the techniques described herein relate to a method, wherein the adhesion promoter is a structure of formula I:

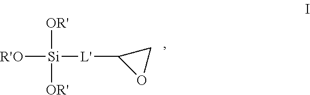

wherein each R′ is independently a C₁-C₆ alkyl group, and L′ is an alkyl linker group.

In some embodiments, the techniques described herein relate to a method, wherein each R′ is independently a methyl or an ethyl group.

In some embodiments, the techniques described herein relate to a method, wherein L′ is a C₂-C₁₀-alkyl linker group.

In some embodiments, the techniques described herein relate to a method, wherein L′ is a substituted C₂-C₁₀-alkyl linker group.

In some embodiments, the techniques described herein relate to a method, wherein one or more carbon atoms in L′ is be substituted with a heteroatom.

In some embodiments, the techniques described herein relate to a method, wherein the adhesion promoter is a structure of formula II:

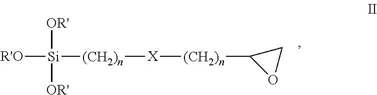

wherein each R′ is independently a methyl or an ethyl group, X is a heteroatom, and each n is independently 1-6.

In some embodiments, the techniques described herein relate to a method, wherein each R′ is a methyl group, X is oxygen, and each n is independently 1-3.

In some embodiments, the techniques described herein relate to a method, wherein the adhesion promoter is

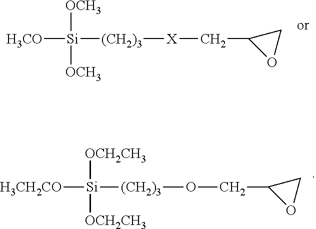

In some embodiments, the techniques described herein relate to a method, wherein the adhesion promoter includes an alkoxysilane.

In some embodiments, the techniques described herein relate to a method, wherein the adhesion promoter includes a methoxysilyl or an ethoxysilyl group.

In some embodiments, the techniques described herein relate to a method, wherein the adhesion promoter includes a dendrimeric compound, more specifically a poly(amidoamine) dendrimeric compound, and even more specifically a generation 2 poly(amidoamine) dendrimeric compound or a hydrophobe substituted poly(amidoamine) dendrimeric compound, such as a C12 hydrophobe.

In some embodiments, the techniques described herein relate to a method, including the further step of dissolving an acid stabilizer in the at least one dissolving agent.

In some embodiments, the techniques described herein relate to a method, wherein the acid stabilizer is a C₆₋₁₂ α-branched alkanoic acid.

In some embodiments, the techniques described herein relate to a method, wherein the acid stabilizer is an α-branched decanoic acid isomer.

In some embodiments, the techniques described herein relate to a method, wherein the acid stabilizer is 2,2-dimethylhexanoic acid or 2,2-dimethylnonanoic acid.

In some embodiments, the techniques described herein relate to a method, wherein the at least one dissolving agent includes a limonene or a terpineol.

In some embodiments, the techniques described herein relate to a method, including the further step of dissolving an acid stabilizer in the at least one dissolving agent.

In some embodiments, the techniques described herein relate to a method, wherein the conductive ink composition has a concentration of about 1 to about 50 weight percent silver decanoate.

In some embodiments, the techniques described herein relate to a method, wherein the conductive ink composition has a viscosity from about 5 centipoise to about 50 centipoise.

In some embodiments, the techniques described herein relate to a method, wherein the silver decanoate is decarboxylated at a temperature of 180° C. or less to form a conductive structure.

In some embodiments, the techniques described herein relate to a method, wherein the silver decanoate is decarboxylated at a temperature of 150° C. or less to form a conductive structure.

In some embodiments, the techniques described herein relate to a method of applying any of the above conductive ink compositions to a substrate; and heating the conductive ink composition on the substrate to a temperature of about 250° C. or less to form the conductive structure.

In some embodiments, the techniques described herein relate to a method, wherein the conductive ink composition is applied by slot die coating, spin coating, roll-to-roll printing, including gravure, flexography, rotary screen printing, screen printing, aerosol jet printing, inkjet printing, airbrushing, Mayer rod coating, flood coating, 3D printing, dispenser, or electrohydrodynamic printing.

In some embodiments, the techniques described herein relate to a method, wherein the conductive structure has a resistance of no more than 5 ohms per square, no more than 2 ohms per square, no more than 1 ohm per square, or no more than 0.5 ohms per square.

In some embodiments, the techniques described herein relate to a method, wherein the conductive structure has a bulk silver content of at least 1%.

### BRIEF DESCRIPTION OF THE DRAWINGS

FIGS. 1A-1C show time courses for the in situ thermal curing of conductive ink compositions containing nonaromatic dissolving agents at different temperatures.

FIG. 2 shows the time course for in situ thermal curing at 135° C. of ink compositions comprising increasing concentrations of an acid stabilizer.

FIGS. 3A and 3B show time courses for the in situ thermal curing of ink compositions that include or do not include an adhesion promoter.

FIG. 4 summarizes features and properties of conductive ink formulations containing non-aromatic solvents.

FIGS. 5A-5D show the physical properties and stabilities of conductive ink formulations comprising a preferred adhesion promoter.

FIGS. 6A-6F show exemplary conductive structures prepared using ink formulations comprising a preferred adhesion promoter.

FIGS. 7A-7B show exemplary conductive structures prepared using ink formulations comprising preferred adhesion promoters.

FIG. 8 shows the physical and electrical properties of conductive structures prepared using ink formulations comprising alternative preferred adhesion promoters.

FIG. 9 shows the stability of conductive structures prepared using ink formulations comprising alternative preferred adhesion promoters.

FIG. 10 shows high temperature storage (HTS) testing of conductive structures prepared using ink formulations comprising alternative preferred adhesion promoters.

FIG. 11 is an image of an inkjet printer nozzle plate in the process of printing a fresh preparation of an ink formulation comprising alternative preferred adhesion promoters.

FIGS. 12A and 12B are images of an inkjet printer nozzle plate in the process of printing preparations of an ink formulation comprising an alternative preferred adhesion promoter stored under different conditions. FIG. 12C shows the physical and electrical properties of conductive structures prepared from an ink formulation comprising an alternative preferred adhesion promoter on two different substrates.

FIG. 13 shows an image of an inkjet printer nozzle plate in the process of printing an ink formulation comprising an alternative preferred adhesion promoter stored at high temperature.

FIG. 14 shows the properties of conductive structures prepared on different substrates from an ink formulation comprising an alternative preferred adhesion promoter stored at low temperature.

FIGS. 15A and 15B illustrate the stability of Formulation 22 over time at 60° C. and 40° C., respectively. FIG. 15C shows the viscosity and surface tension for various ink formulations.

FIG. 16A shows the effect of water on the stability of ink formulations comprising an alternative preferred adhesion promoter stored at low temperature. FIG. 16B shows the effect of water on the stability of an ink formulation comprising an alternative preferred adhesion promoter stored at high temperature.

FIG. 17 shows the properties of conductive structures prepared using an ink formulation comprising an alternative preferred adhesion promoter that had been treated with water.

### DETAILED DESCRIPTION OF THE INVENTION

Ink compositions derived from silver metal precursors have been described in PCT International Publication No. WO2013/096664A1, which is incorporated herein by reference in its entirety. Further conductive ink compositions are described, for example, in PCT International Publication No. WO2015/160938A1, which is also incorporated herein by reference in its entirety. Although these ink compositions are advantageously free of metallic particles, they typically require a catalyst, for example an amine-containing catalyst, to facilitate decarboxylation of the silver complexes, and thus formation of the conductive metallic structures at low temperatures.

Disclosed herein are improved conductive ink compositions formed by making silver complexes that do not require high decomposition temperatures. The disclosed conductive ink compositions advantageously comprise a silver decanoate comprising at least one α-branched silver decanoate isomer. In preferred embodiments, the improved conductive ink compositions do not require a catalyst to decarboxylate the silver complex. By employing lower decomposition temperatures and reduced tack times to form the conductive structures, the improved conductive ink compositions are compatible with more substrates that do not require high processing temperatures to maintain integrity. Furthermore, the methods for making the conductive ink compositions are both simple and result in a high yield of conductive structures.

The conductive ink compositions may possess low viscosity so that they are compatible with a broad range of patterning techniques, including slot die coating, spin coating, roll-to-roll printing, including gravure, flexography, rotary screen printing, screen-printing, aerosol jet printing, inkjet printing, airbrushing, Mayer rod coating, flood coating, 3D printing, and electrohydrodynamic printing. In particular, the inks are compatible with inkjet printing, dip coating, and spray coating. The patterned features may be highly conductive at room temperature and achieve bulk conductivity upon decomposing at mild temperatures (e.g., in some cases at less than about 100° C.). Finally, the ink compositions may remain stable at room temperature for months without particle precipitation.

Accordingly, conductive ink compositions (also referred to as “conductive inks” or “inks”) have been created for printing highly conductive features at low temperatures. Such inks may be stable, particle-free, and suitable for a wide range of patterning techniques. In some embodiments, a “particle-free” ink is one that does not include any particles at a diameter of greater than about 10 nm. In some embodiments, a “particle-free” ink is one that has less than about 1% particles, preferably less than about 0.1% particles. Silver salts are employed in the inks as a precursor material, which ultimately yields the silver in the conductive silver coatings, lines, or patterns. Any suitable silver precursor may be used.

In one aspect, a conductive ink composition includes a silver complex formed by mixing a silver carboxylate and at least one dissolving agent. In preferred embodiments, the silver carboxylate is soluble in the dissolving agent. Solubility, as known to one of ordinary skill, is the property of a substance, such as a silver carboxylate, to dissolve in a solvent, such as a dissolving agent. In some embodiments, the silver complex is first applied to a substrate. In some embodiments, the silver carboxylate is converted to a conductive silver structure at a temperature of about 250° C. or less. In some embodiments, the silver carboxylate is converted to a conductive silver structure at a temperature of about 100° C. or less. In some embodiments, the silver carboxylate is converted to a conductive silver structure at a temperature of about 220° C., of about 210° C. or less, of about 190° C. or less, of about 180° C. or less, of about 170° C. or less, of about 160° C. or less, of about 150° C. or less, of about 140° C. or less, of about 130° C. or less, of about 120° C. or less, of about 110° C. or less, of about 90° C. or less, of about 80° C. or less, of about 70° C. or less, of about 60° C. or less, or of about 50° C. or less.

### Silver Carboxylates

The silver carboxylates of the instant conductive ink compositions include silver salts of aliphatic carboxylic acids. In some embodiments, the silver carboxylate includes silver salts of long-chain aliphatic carboxylic acids. In specific embodiments, the silver carboxylate includes silver salts of long chain aliphatic carboxylic acids having 5 to 15 carbon atoms, 8 to 12 carbon atoms, or even 9 to 11 carbon atoms.

In preferred embodiments, the silver carboxylate of the instant compositions comprises a particular silver decanoate isomer or mixture of silver decanoate isomers. For example, in some embodiments, at least one decanoic acid isomer used to generate the silver decanoate of the conductive ink composition has the following structure:

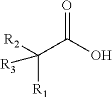

wherein R₁ and R₂ is each independently an alkyl group, wherein R₃ is either hydrogen or an alkyl group, and wherein R₁, R₂, and R₃ together comprise eight total carbon atoms. The silver decanoate formed from the above decanoic acid isomer accordingly has the following structure:

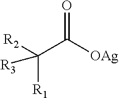

wherein the R₁, R₂, and R₃ groups have the definitions provided above. Such structures will be referred to herein as α-branched silver decanoate isomers.

In some embodiments, the R₁ and R₂ group of the α-branched silver decanoate isomer is each independently methyl or ethyl.

In specific embodiments, at least one decanoic acid isomer used to generate the silver decanoate of the instant conductive ink composition can, for example, be 2,2-dimethyloctanoic acid, 2,2,3,5-tetramethylhexanoic acid, 2,4-dimethyl-2-isopropylpentanoic acid, 2,5-dimethyl-2-ethylhexanoic acid, 2,2-diethylhexanoic acid, 2-butylhexanoic acid, or any combination of these α-branched decanoic acid isomers.

Corresponding silver carboxylates can be formed from each of these decanoic acid isomers, as described in the Examples section, and as would be understood by those of ordinary skill in the art. Specifically, the silver decanoate isomers can accordingly be, for example, an α-branched silver decanoate isomer, such as silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or any combination of these compounds.

The silver carboxylate is preferably not formed from a linear alkanoic acid. For example, the silver carboxylate is preferably not formed from n-decanoic acid.

In embodiments, an amount from about 0.4 grams to about 1.0 grams of a silver carboxylate, specifically a silver decanoate comprising at least one α-branched silver decanoate isomer, is dissolved per gram of the dissolving agent. In some embodiments, about 0.4 grams, about 0.5 grams, about 0.6 grams, about 0.7 grams, about 0.8 grams, about 0.9 grams, or even about 1.0 grams of the silver carboxylate, specifically the at least one or more α-branched silver decanoate isomers, is dissolved per gram of the dissolving agent.

### Dissolving Agents

As mentioned above, the instant conductive ink compositions comprise at least one dissolving agent that is capable of dissolving the disclosed silver carboxylates, preferably fully dissolving the silver carboxylates, to generate a particle-free conductive ink composition. Specifically, the dissolving agent acts as a stabilizer and a solvent but is not intended to act as a reducing agent for the silver carboxylate. In some embodiments, the dissolving agent has a boiling point of about 250° C. or less. In some embodiments, the dissolving agent has a boiling point of about 200° C. or less. In some embodiments, the dissolving agent has a boiling point of about 100° C. or less. In some embodiments, the dissolving agent has a boiling point of about 220° C. or less, about 210° C. or less, about 190° C. or less, about 180° C. or less, about 170° C. or less, about 160° C. or less, about 150° C. or less, of about 140° C. or less, of about 130° C. or less, of about 120° C. or less, of about 110° C. or less, of about 90° C. or less, of about 80° C. or less, of about 70° C. or less, of about 60° C. or less, or of about 50° C. or less.

In some embodiments, the dissolving agent may be selected based on the type of silver carboxylate used to make the ink composition. In some embodiments, the dissolving agent may be selected based on the boiling point/tack time for a specific application. In some embodiments, the dissolving agent may be selected based on the type of substrate the ink composition will be applied to for compatibility and wettability issues. For example, for deposition methods such as inkjet printing or e-jet, greater stability is generally preferred, and thus it may be preferable to use a dissolving agent with a higher boiling point.

In some embodiments, the dissolving agent comprises an alkane hydrocarbon, a carbamate, an alkene, a cyclic hydrocarbon, an aromatic hydrocarbon, an amine, a polyamine, an amide, an ether, an ester, an alcohol, a thiol, a thioether, a phosphine, or a combination thereof.

In some embodiments, the dissolving agent comprises an organic solvent. In some embodiments, the dissolving agent comprises one or more linear or branched alkane hydrocarbons of length C₅₋₂₀. For example, the dissolving agent may comprise a pentane, a hexane, a heptane, an octane, a nonane, a decane, an undecane, a dodecane, a tridecane, a tetradecane, a pentadecane, a hexadecane, an octadecane, a nonadecane, or an icosane.

In some embodiments, the dissolving agent comprises one or more cyclic hydrocarbons of length C₆₋₁₀. For example, the dissolving agent may comprise a cyclohexane, a cycloheptane, a cyclooctane, a cyclononane, a cyclodecane, or a decalin. In some embodiments, the dissolving agent comprises an aromatic hydrocarbon. For example, the dissolving agent may comprise benzene, a toluene, a xylene, or a tetralin. In some embodiments, the dissolving agent comprises a xylene.

In some embodiments, the dissolving agent comprises a linear ether, a branched ether, or a cyclic ether. In some embodiments, the dissolving agent comprises a linear or branched ether. For example, the dissolving agent may comprise dimethyl ether, diethyl ether, dipropyl ether, dibutyl ether, or methyl t-butyl ether. In some embodiments, the dissolving agent comprises one or more cyclic ethers. For example, the dissolving agent can comprise tetrahydrofuran, tetrahydropyran, dihydropyran, or 1,4-dioxane.

In some embodiments, the dissolving agent comprises an alcohol. In some embodiments, the dissolving agent comprises a primary alcohol, a secondary alcohol, or a tertiary alcohol. In some embodiments, the alcohol comprises a propanol, a butanol, a pentanol, a hexanol, an octanol, or combinations thereof. In some embodiments, the alcohol comprises 1-propanol, 2-propanol, l-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, or a combination thereof.

In some embodiments, the dissolving agent comprises a ketone. More specifically, in some embodiments, the dissolving agent comprises actylacetone.

The dissolving agent used in the instant conductive ink compositions is ideally suitable for use at an industrial scale in mass production. In some embodiments, it can therefore be advantageous for the dissolving agent to be non-toxic and/or to be less damaging to the environment than is the case for many commonly-used organic solvents. In some embodiments, it can be advantageous for the dissolving agent to have a higher flash point than is the case for many commonly-used organic solvents. In some embodiments, it can be advantageous for the dissolving agent to be subject to fewer regulations than is the case for many commonly-used organic solvents. For example, aromatic hydrocarbons such as xylene, toluene, mesitylene, and the like, are highly regulated in most industrial countries. The use alternatives to these solvents can therefore be advantageous. In addition, conductive inks formulated from aromatic hydrocarbons can have flash points that are lower than 60° C. and that are therefore not typically acceptable in mass production environments. Accordingly, in some embodiments, the dissolving agent of the instant conductive ink compositions does not comprise an aromatic hydrocarbon.

In preferred embodiments, the dissolving agent comprises a terpene, a terpenoid, or a combination thereof. For example, in some embodiments, the dissolving agent comprises a pinene, a limonene, in particular a D-limonene, a terpineol, or a combination thereof. In preferred embodiments, the dissolving agent comprises limonene. In other preferred embodiments, the dissolving agent comprises terpineol. In still other preferred embodiments, the dissolving agent comprises a combination of limonene and terpineol.

Not all terpenes and terpenoids are suitable for use in the conductive ink compositions of the instant disclosure. For example, in some embodiments, the instant dissolving agent does not comprise alpha-terpinene, gamma-terpinene, terpinolene, or terpene-4-ol. Alternatively, or in addition, in some embodiments, it can be advantageous for the dissolving agent to be a purified form of the dissolving agent. For example, in some embodiments, the dissolving agent is a purified terpineol, a purified limonene, or a combination of a purified terpineol and a purified limonene. A purified dissolving agent is understood to be at least 95% pure, at least 97% pure, at least 98% pure, at least 99% pure, or even more pure.

In some embodiments, an amount of dissolving agent is added so that the silver carboxylate is substantially dissolved or completely dissolved in the dissolving agent. In some embodiments, “substantially dissolved” means the silver carboxylate has a solubility in the dissolving agent at 25° C. of at least about 200 g/L, at least about 300 g/L, at least about 400 g/L, or even higher. In embodiments where the silver carboxylate is substantially dissolved or completely dissolved in the dissolving agent, the conductive ink composition can be considered particle-free.

In some embodiments, the conductive ink composition comprises two or more dissolving agents. In some embodiments, the volume ratio of two dissolving agents in the conductive ink is about 1 to about 1 of the first dissolving agent to the second dissolving agent. In some embodiments, the volume ratio of two dissolving agents in the conductive ink is about 2 to about 1 of the first dissolving agent to the second dissolving agent. In some embodiments, the volume ratio of two dissolving agents is about 3 to about 1 of the first dissolving agent to the second dissolving agent. In some embodiments, the volume ratio of two dissolving agents is about 4 to about 1 of the first dissolving agent to the second dissolving agent.

In some embodiments, the flash point of the conductive ink composition can be varied by varying the volume ratio of two or more dissolving agents in the conductive ink. For example, in some embodiments, the flash point of the conductive ink composition is increased by increasing the relative amount of a dissolving agent that has a higher flash point compared to a dissolving agent that has a lower flash point. More specifically, in some embodiments, the flash point of the conductive ink composition is modulated by varying the ratio of a limonene to a terpineol in the conductive ink composition. Even more specifically, the flash point of the conductive ink composition can be decreased by increasing the ratio of a limonene to a terpineol in the conductive ink composition.

### Acid Stabilizers

In another aspect are provided conductive ink compositions that further comprise an organic acid to stabilize the ink composition. Although it should be understood that residual organic acids can remain present at low levels in the silver carboxylates of the instant conductive ink compositions (e.g., in the silver decanoate preparations described below), even if no additional organic acid is added to the formulation, it can in some cases be advantageous for an acid stabilizer to be added to the conductive ink formulations of the instant disclosure. For example, the presence of an acid stabilizer in the conductive ink formulations can increase the stability of the formulations, particularly during storage at elevated temperatures (e.g., at 30° C. or 40° C.). Without intending to be bound by theory, it is believed that the presence of an acid stabilizer in these formulations inhibits the formation of metallic silver during storage.

In some embodiments, the added acid stabilizer is a C₆₋₁₂ α-branched alkanoic acid. In preferred embodiments, the added acid stabilizer is one or more of the decanoic acid isomers used to generate the silver decanoate of the instant conductive ink compositions. For example, the added acid stabilizer can be an α-branched decanoic acid isomer. In other preferred embodiments, the added acid stabilizer is 2,2-dimethylhexanoic acid or 2,2-dimethylnonanoic acid.

The added acid stabilizer is preferably not a linear alkanoic acid. For example, the added acid stabilizer is preferably not n-heptanoic acid, n-octanoic acid, or n-decanoic acid. The added acid stabilizer is also preferably not a secondary alkanoic acid, such as 2-butyl hexanoic acid.

The added acid stabilizer is preferably included in a conductive ink composition in amounts ranging from 0 to 15% by weight. In some embodiments, the added acid stabilizer is included at about 0.5% by weight, about 1.5% by weight, about 5% by weight, about 10% by weight, or even about 15% by weight.

### Adhesion Promoter

In another aspect are provided conductive ink compositions that further comprise an adhesion promoter to increase adhesion of the ink to the substrate on which it is printed. It is envisioned that any agent that both improves the adhesive properties of the ink and that does not significantly degrade either the fluidic or other physical properties of the ink composition, including stability of the ink composition, or the electrical or other physical properties of conductive structures that are generated using the ink, can be utilized as an adhesion promoter in the instant ink compositions.

It should be understood that one or more adhesion promoters and one or more acid stabilizers can be included in the conductive ink compositions of the instant disclosure, either together, or separately, in any combination.

The adhesion promoter is preferably chosen in coordination with the choice of substrate on which the ink will be printed.

In some embodiments, the adhesion promoter comprises a reactive silane. Reactive silanes are known in the chemical and material science arts to enhance the performance of coatings. For example, they can improve adhesion to inorganic substrates, provide crosslinking, improve the dispersion of components of a composition, improve hydrophobicity, and scavenge moisture. In specific embodiments, the reactive silane comprises an alkoxysilane group, for example a trialkoxysilyl group. In some embodiments the alkoxysilyl group can be oligomerized or polymerized into a number of different chain length configurations. In some embodiments, the adhesion promoter comprises an alkyl group, and more specifically an alkyl group that comprises a second reactive moiety. For example, the adhesion promoter can comprise a polyalkene, for example a poly-1,2-butadiene. Suitable adhesion promoters are commercially available, for example from Gelest, Inc., Morrisville, PA, USA.

In some embodiments, the adhesion promoter comprises an epoxy group. More specifically, the adhesion promoter can comprise an epoxy group coupled to a silane, for example any of the just-described reactive silanes. In some embodiments, the adhesion promoter can comprise an epoxy group coupled to an alkoxysilane group, such as a trialkoxysilyl group. In specific embodiments, the adhesion promoter can comprise an epoxy group coupled to a trialkoxysilyl group, such as a trimethoxysilyl group or a triethoxysilyl group.

The adhesion promoter preferably comprises a linker group that couples a reactive silane group to second reactive group, for example an alkyl group comprising a reactive constituent such as a polyalkene or an epoxy group. The linker group can be any suitable chemical linker. In some embodiments, the linker group is an alkyl linker group, for example a C₂-C₁₀-alkyl linker group. In some embodiments, the linker group is a substituted alkyl linker group, where the alkyl linker group is substituted with any suitable substituent. For example, the alkyl linker group can be substituted with one or more alkyl, alkenyl, alkynyl, alkoxy, alkanoyl, alkylamino, hydroxy, thio, amino, alkanoylamino, alkylcarboxy, carbonate, halo, nitro, cyano groups, or the like. In some embodiments, one or more of the carbon atoms in the linker can be substituted with a suitable heteroatom. In specific embodiments, the heteroatom can be oxygen, sulfur, or nitrogen, in any combination. More specifically, the heteroatom can be oxygen.

In some embodiments, the adhesion promoter is a structure of formula I:

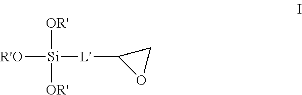

wherein each R′ is independently a C₁-C₆ alkyl group, and L′ is an alkyl linker group. In more specific embodiments of structural formula I, each R′ is independently a methyl or an ethyl group. In other more specific embodiments of structural formula I, L′ can be a C₂-C₁₀-alkyl linker group, including a substituted C₂-C₁₀-alkyl linker group. In some embodiments of structural formula I, one or more of the carbon atoms in L′ can be substituted with a suitable heteroatom, for example an oxygen, a sulfur, or a nitrogen, in any combination. More specifically, the heteroatom can be oxygen.

In some more specific embodiments, the adhesion promoter is a structure of formula II:

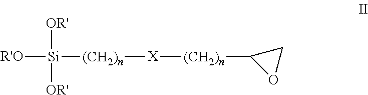

wherein each R′ is independently a methyl or an ethyl group, X is a heteroatom, and each n is independently 1-6. In some embodiments of structural formula II, each R′ is a methyl group, X is oxygen, and each n is independently 1-3.

In some specific embodiments, the adhesion promoter of the instant conductive ink compositions is:

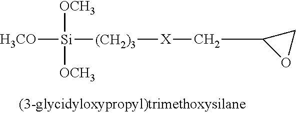

As is described in more detail below, this compound is readily soluble in typical ink formulations. Specifically, ink formulations including this adhesion promoter can be prepared at 0.1-0.5% without reducing the conductivity of structures produced from the inks on different substrates. Furthermore, inks comprising this adhesion promoter are stable at 40° C. over 14-30 days with no visible precipitation or plating. These formulations likewise display viscosities suitable for use with typical industrial inkjet printhead technologies. Addition of water in the ink formulations up to 3% does not decrease stability of these inks at 40° C.

In some specific embodiments, the adhesion promoter of the instant conductive ink compositions is:

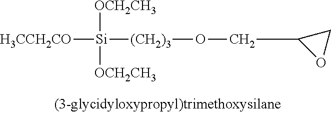

Exemplary conductive ink formulations comprising this compound are exemplified below, including formulations comprising different acid and non-acid stabilizers.

In some embodiments, the adhesion promoter does not contain a silane.

In some embodiments, the adhesion promoter can be or comprise a dendrimeric compound. More specifically, the dendrimeric compound can be a poly(amidoamine) (PAMAM) dendrimeric compound. PAMAMs are typically made of repetitive subunits of amide and amine functionality with tree-like branching. They have a sphere-like shape overall, with high molecular uniformity, narrow molecular weight distribution, and defined size and shape characteristics. PAMAM dendrimers are typically prepared from a central core in an iterative manufacturing process, with each subsequent step representing a new “generation” (G) of dendrimer. For example, G0 has 4 surface groups, G1 has 8 surface groups, G2 has 16 surface groups, G3 has 32 surface groups, G4 has 64 surface groups, G5 has 128 surface groups, and so on. The surface groups, typically primary amino groups, represent available attachment sites for the further modification. For example, the surface groups can be unmodified, so as to provide an amino surface PAMAM, or they can be further modified, so as to provide an amidoethanol (i.e., hydroxy) surface PAMAM, a succinamic acid surface PAMAM, a sodium carboxylate surface PAMAM, a hydrophobe substituted PAMAM, or any other surface-modified PAMAM. In some cases, the PAMAM dendrimer can have a mixture of any of these surface modifications.

In preferred embodiments, the adhesion promoter is or comprises a generation 2 (G2) PAMAM compound, for example a dendrimeric compound comprising the following core structure:

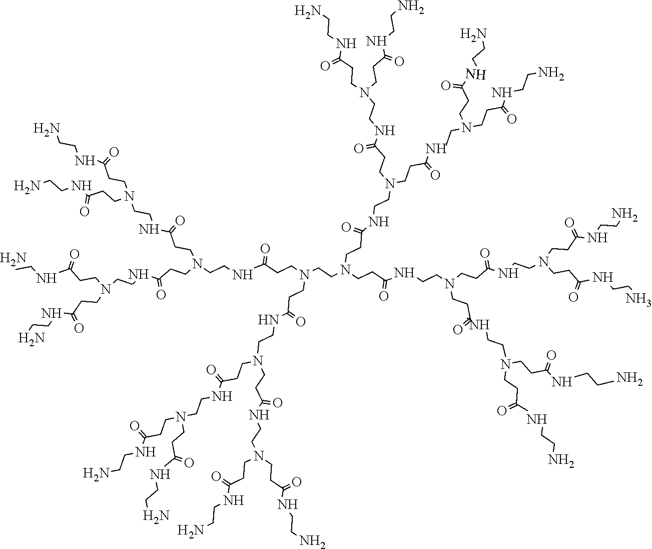 [SMILES: NCCNC(=O)CCN(CCNC(=O)CCN(CCNC(=O)CCN(CCC(=O)NCCN(CCC(=O)NCCN(CCC(=O)NCCN)CCC(=O)NCCN)CCC(=O)NCCN(CCC(=O)NCCN)CCC(=O)NCCN)CCN(CCC(=O)NCCN(CCC(=O)NCCN(CCC(=O)NCCN)CCC(=O)NCCN)CCC(=O)NCCN(CCC(=O)NCCN)CCC(=O)NCCN)CCC(=O)NCCN(CCC(=O)NCCN(CCC(=O)NCCN)CCC(=O)NCCN)CCC(=O)NCCN(CCC(=O)NCCN)CCC(=O)NCCN)CCC(=O)NCCN(CCC(=O)NCCN)CCC(=O)NCCN)CCC(=O)NCCN]

In other preferred embodiments, the adhesion promoter is or comprises a hydrophobe substituted PAMAM, for example a C12 hydrophobe substituted PAMAM. In some embodiments, the hydrophobe substituted PAMAM is a 25% or 50% mixed amine/hydrophobe substituted PAMAM. In some embodiments, the hydrophobe substituted PAMAM is a G2, G3, or G4 hydrophobe substituted PAMAM. In highly preferred embodiments, the adhesion promoter is a G2-50% C12 hydrophobe substituted PAMAM.

Exemplary conductive ink formulations comprising a G2-50% C12 hydrophobe substituted PAMAM are exemplified below, including formulations comprising different acid and non-acid stabilizers.

Dendrimeric compounds suitable for use as adhesion promoters in the conductive ink compositions disclosed herein are available, for example, from Dendritech, Inc. (www.dendritech.com).

In some embodiments, the adhesion promoter does not comprise a dendrimeric compound.

### Particle-Free Conductive Ink Compositions

Provided herein are conductive ink compositions comprising the above silver carboxylates. For example, in some embodiments, the silver carboxylate is a silver decanoate, wherein the silver decanoate comprises at least one α-branched silver decanoate isomer, as described above. In some embodiments, the at least one α-branched silver decanoate isomer is the silver salt of 2,2-dimethyloctanoic acid, 2,2,3,5-tetramethylhexanoic acid, 2,4-dimethyl-2-isopropylpentanoic acid, 2,5-dimethyl-2-ethylhexanoic acid, 2,2-diethylhexanoic acid, 2-butylhexanoic acid, or any combination of these α-branched decanoic acid isomers.

In some embodiments, the instant conductive ink compositions do not contain a catalyst. In particular, when the silver carboxylate is a silver decanoate, for example a silver decanoate comprising at least one α-branched silver decanoate isomer, or a mixture of different α-branched silver decanoate isomers, it may not be necessary to include a catalyst in the composition, let alone a catalyst comprising an amine. Accordingly, in these embodiments, conductive structures can be formed from the conductive ink compositions by heating the silver complex at a temperature of about 250° C. or less to form the conductive structure.

In some embodiments, the conductive ink composition has a concentration of about 1 to about 50 weight percent silver of the conductive ink composition. In some embodiments, the conductive ink composition has a concentration of about 1 to about 40 weight percent silver of the conductive ink composition. In some embodiments, the conductive ink composition has a concentration of about 1 to about 30 weight percent silver of the conductive ink composition. In some embodiments, the conductive ink composition has a concentration of about 1 to about 20 weight percent silver of the conductive ink composition. In some embodiments, the conductive ink composition has a concentration of about 1 to about 10 weight percent silver of the conductive ink composition. In some embodiments, the conductive ink composition has a concentration of about 5 to about 15 weight percent silver of the conductive ink composition. In some embodiments, the conductive ink composition has a concentration of about 1 weight percent, about 2 weight percent, about 3 weight percent, about 4 weight percent), about 5 weight percent, about 6 weight percent, about 7 weight percent, about 8 weight percent, about 9 weight percent, about 10 weight percent), about 11 weight percent), about 12 weight percent, about 13 weight percent, about 14 weight percent, about 15 weight percent, about 16 weight percent), about 17 weight percent), about 18 weight percent, about 19 weight percent, about 20 weight percent, about 21 weight percent, about 22 weight percent), about 23 weight percent, about 24 weight percent, about 25 weight percent, about 26 weight percent, about 27 weight percent, about 28 weight percent), about 29 weight percent, about 30 weight percent, about 31 weight percent, about 32 weight percent, about 33 weight percent, about 34 weight percent), about 35 weight percent, about 36 weight percent, about 37 weight percent, about 38 weight percent, about 39 weight percent, about 40 weight percent, about 41 weight percent, about 42 weight percent, about 43 weight percent, about 44 weight percent, about 45 weight percent, about 46 weight percent, about 47 weight percent, about 48 weight percent, about 49 weight percent, about 50 weight percent, or even higher weight percent silver in the conductive ink composition.

In some embodiments, the conductive ink composition comprises one or more of the above-described dissolving agents, in any combination.

In some embodiments, the conductive ink composition comprises one or more of the above-described adhesion promoters, in any combination.

In some embodiments, the conductive ink composition comprises one or more of the above-described acid stabilizers, in any combination.

In some embodiments, the electrical conductivity of the conductive structure formed from the conductive ink composition is measured. In some embodiments, the electrical conductivity of the conductive structure is from about 2×10⁻⁶ Ohm-cm to about 1×10⁻⁵ Ohm-cm. In some embodiments, the electrical conductivity of the conductive structure is from about 3×10⁻⁶ Ohm-cm to about 6×10⁻⁶ Ohm-cm. In some embodiments, the electrical conductivity of the conductive structure is at least about 2×10⁻⁶ Ohm-cm, about 3×10⁻⁶ Ohm-cm, about 4×10⁻⁶ Ohm-cm, about 5×10⁻⁶ Ohm-cm, about 6×10⁻⁶ Ohm-cm, about 7×10⁻⁶ Ohm-cm, about 8×10⁻⁶ Ohm-cm, or about 9×10⁻⁶ Ohm-cm. In some embodiments, the electrical conductivity of the conductive structure is at most about 1×10⁻⁵ Ohm-cm, about 9×10⁻⁶ Ohm-cm, about 8×10⁻⁶ Ohm-cm, about 7×10⁻⁶ Ohm-cm, about 6×10⁻⁶ Ohm-cm, about 5×10⁻⁶ Ohm-cm, about 4×10⁻⁶ Ohm-cm, or about 3×10⁻⁶ Ohm-cm.

The electrical conductivity of the conductive structure may in some embodiments be expressed in terms of sheet resistance (i.e., bulk resistivity divided by thickness) in units of ohms per square (also referred to as ohms/square or OPS). For example, in some embodiments, the resistance of the conductive structure is no more than 5 ohms per square, no more than 2 ohms per square, no more than 1 ohm per square, no more than 0.5 ohms per square, or even lower. Preferably, the resistance of the conductive structure is no more than 1 ohm per square.

The conductive ink compositions of the instant disclosure can be used to form conductive structures having high levels of bulk silver. Specifically, in some embodiments, the conductive structure has a bulk silver content of at least 1%. In more specific embodiments, the conductive structure has a bulk silver content of at least 2%, at least 5%, at least 10%, at least 15%, at least 20%, or even higher.

### Methods for Making Conductive Ink Compositions

According to another aspect, the disclosure provides methods for making a conductive ink composition, in particular a conductive ink composition as described above. These methods comprise the step of dissolving a silver decanoate in at least one dissolving agent to form a conductive ink composition, wherein the silver decanoate comprises at least one α-branched silver decanoate isomer, for example, any of the silver decanoates described above.

In some embodiments, the methods comprise the further step of dissolving an adhesion promoter, including one or more of any of the above-described adhesion promoters, and/or an acid stabilizer, including one or more of any of the above-described acid stabilizers in the at least one dissolving agent.

### Methods for Forming a Conductive Structure

In another aspect are disclosed methods of making conductive structures. In some embodiments, the methods include the step of dissolving the silver carboxylate in at least one dissolving agent to form a conductive ink composition. In some embodiments, the methods also include the step of applying the conductive ink composition to a substrate. In some embodiments, the methods include the step of heating the conductive ink composition on the substrate at a decomposition temperature of about 250° C. or less to form the conductive structure. In some embodiments, the methods include the step of heating the conductive ink composition on the substrate at a decomposition temperature of about 100° C. or less to form the conductive structure. In some embodiments, the methods include the step of heating the conductive ink composition on the substrate at a decomposition temperature of about 210° C. or less, of about 200° C. or less, of about 190° C., of about 180° C. or less, of about 170° C. or less, of about 160° C., of about 150° C. or less, of about 140° C. or less, of about 130° C. or less, of about 120° C. or less, of about 110° C. or less, of about 90° C. or less, of about 80° C. or less, of about 70° C. or less, of about 60° C. or less, or of about 50° C. or less to form the conductive structure. In some embodiments, the conductive ink composition is heated with a heat source. Examples of heat sources include an IR lamp, oven, or a heated substrate.

In preferred embodiments, the conductive ink compositions of the instant methods do not comprise a catalyst. More specifically, in some embodiments, the conductive ink compositions of the instant methods do not comprise a catalyst comprising an amine.

In some embodiments, the conductive ink composition of the instant methods has a desired viscosity. In some embodiments, the desired viscosity is obtained using a micro VISC viscometer. In some embodiments, the conductive ink composition has a viscosity from about 50 centipoise to about 1000 centipoise. In some embodiments, the conductive ink composition has a viscosity from about 5 centipoise to about 50 centipoise. In some embodiments, the conductive ink composition has a viscosity from about 10 centipoise to about 40 centipoise. In some embodiments, the conductive ink composition has a viscosity from about 20 centipoise to about 30 centipoise. In some embodiments, the conductive ink composition has a viscosity from about 18 centipoise to about 20 centipoise. In some embodiments, the conductive ink composition has a viscosity of about 18, about 19, or about 20 centipoise. In some embodiments, the conductive ink composition has a viscosity of at least about 5 centipoise, about 10 centipoise, about 20 centipoise, about 30 centipoise, about 40 centipoise, about 50 centipoise, about 60 centipoise, about 70 centipoise, about 80 centipoise, about 90 centipoise, about 100 centipoise, about 200 centipoise, about 300 centipoise, about 400 centipoise, about 500 centipoise, about 600 centipoise, about 700 centipoise, about 800 centipoise, or about 900 centipoise. In some embodiments, the conductive ink composition has a viscosity of at most about 1000 centipoise, about 900 centipoise, about 800 centipoise, about 700 centipoise, about 600 centipoise, about 500 centipoise, about 400 centipoise, about 300 centipoise, about 200 centipoise, about 100 centipoise, about 90 centipoise, about 80 centipoise, about 70 centipoise, about 60 centipoise, about 50 centipoise, about 40 centipoise, about 30 centipoise, about 20 centipoise, or about 10 centipoise.

In some embodiments, the viscosity of the conductive ink composition is adjusted based upon the amount of dissolving agent used. In some embodiments, the viscosity of the complex is adjusted based upon the type of dissolving agent used. For example, in embodiments where the dissolving agent comprises limonene and terpineol, an increase in the percentage of terpineol in the conductive ink composition can increase the viscosity of the ink. In some embodiments, the viscosity of silver complex can be tuned from less than 5 centipoise with a large proportion of limonene to 50 centipoise with a large portion of terpineol. Unless otherwise indicated, all viscosity values are for samples at room temperature.

### Applications of the Conductive Ink Compositions

The conductive ink compositions of the instant disclosure can be used in various printing applications, including slot die coating, spin coating, roll-to-roll printing, including gravure, flexography, rotary screen printing, screen printing, aerosol jet printing, inkjet printing, airbrushing, Mayer rod coating, flood coating, 3D printing, dispenser, and electrohydrodynamic printing. In particular, the inks can be used in inkjet printing, dip coating, and spray coating.

Furthermore, patterns can be created using photolithography to create a mask to etch silver from certain areas, thereby creating high-fidelity features. Both positive and negative patterning processes may be used to create the patterns.

In some embodiments, the silver salt of the silver carboxylate is completely dissolved in at least one dissolving agent. The fully dissolved silver salt is compatible with many nonpolar polymer substrates, glasses, and ceramic substrates where polar complexes do not wet particularly well. In some embodiments, the conductive ink composition comprising the silver complex is applied to a polymer substrate, for example a flexible polymer substrate, such as a polyimide (PI) substrate, for example Kapton. In some embodiments, the conductive ink composition comprising the silver complex is applied to a nonpolar polymer substrate. In some embodiments, the conductive ink composition comprising the silver complex is applied to a glass substrate. In some embodiments, the conductive ink composition comprising the silver complex is applied to a ceramic substrate.

Furthermore, elastomers and 3D substrates with specifically non-planar topography can be used in conjunction with the conductive structures. In some embodiments, the conductive ink composition comprising the silver complex is applied to an elastomer. In some embodiments, the conductive ink composition comprising the silver complex is applied to a 3D substrate.

In some embodiments, the conductive ink compositions of the instant disclosure can be applied to an epoxy substrate, such as, for example, an epoxy molding compound (EMC) substrate or the like.

In some embodiments, the conductive ink compositions of the instant disclosure can be applied to a silver nanowire (SNW) substrate, a solder resist substrate (also referred to as a solder mask substrate), or any other suitable substrate material.

In some embodiments, the ink composition of the instant methods has a concentration of about 0.1-50 weight percent metal salt of the ink composition. In some embodiments, the ink composition of the instant methods has a concentration of about 0.1-40 weight percent metal salt of the ink composition. In some embodiments, the ink composition has a concentration of about 1-30 weight percent metal salt of the ink composition. In some embodiments, the ink composition has a concentration of about 1-20 weight percent metal salt of the ink composition. In some embodiments, the ink composition has a concentration of about 1-10 weight percent metal salt of the ink composition. In some embodiments, the ink composition has a concentration of about 5-15 weight percent metal salt of the ink composition. In some embodiments, the ink composition has a concentration of about 0.1 weight percent), about 0.2 weight percent), about 0.3 weight percent>, about 0.4 weight percent>, about 0.5 weight percent>, about 0.6 weight percent>, about 0.7 weight percent, about 0.8 weight percent, about 0.9 weight percent, about 1 weight percent, about 2 weight percent, about 3 weight percent, about 4 weight percent), about 5 weight percent), about 6 weight percent, about 7 weight percent, about 8 weight percent, about 9 weight percent, about 10 weight percent, about 11 weight percent), about 12 weight percent, about 13 weight percent, about 14 weight percent, about 15 weight percent, about 16 weight percent, about 17 weight percent), about 18 weight percent, about 19 weight percent, or about 20 weight percent metal of the ink composition.

In some embodiments, the ink composition of the instant methods has a concentration of at least about 0.1 weight percent, about 0.2 weight percent, about 0.3 weight percent, about 0.4 weight percent, about 0.5 weight percent, about 0.6 weight percent, about 0.7 weight percent, about 0.8 weight percent, about 0.9 weight percent, 1 weight percent, about 2 weight percent, about 3 weight percent, about 4 weight percent), about 5 weight percent), about 6 weight percent, about 7 weight percent, about 8 weight percent, about 9 weight percent, about 10 weight percent, about 11 weight percent), about 12 weight percent, about 13 weight percent, about 14 weight percent, about 15 weight percent, about 16 weight percent, about 17 weight percent), about 18 weight percent, about 19 weight percent, or about 20 weight percent metal salt of the ink composition. In some embodiments, the ink composition has a concentration of at most about 40 weight percent), about 39 weight percent, about 38 weight percent, about 37 weight percent, about 36 weight percent, about 35 weight percent, about 34 weight percent, about 33 weight percent, about 32 weight percent, 31 weight percent, about 30 weight percent, about 29 weight percent, about 28 weight percent, about 27 weight percent), about 26 weight percent, about 25 weight percent, about 24 weight percent, about 23 weight percent, about 22 weight percent, about 21 weight percent), about 20 weight percent, about 19 weight percent, about 18 weight percent, about 17 weight percent, about 16 weight percent, about 15 weight percent, about 14 weight percent, about 13 weight percent, or about 12 weight percent metal salt of the ink composition.

In some embodiments, the ink composition of the instant methods has a concentration of about 0.1-50 weight percent metal complex of the ink composition. In some embodiments, the ink composition of the instant methods has a concentration of about 0.1-40 weight percent metal complex of the ink composition. In some embodiments, the ink composition has a concentration of about 1-30 weight percent metal complex of the ink composition. In some embodiments, the ink composition has a concentration of about 1-20 weight percent metal complex of the ink composition. In some embodiments, the ink composition has a concentration of about 1-10 weight percent metal complex of the ink composition. In some embodiments, the ink composition has a concentration of about 5-15 weight percent metal complex of the ink composition. In some embodiments, the ink composition has a concentration of about 0.1 weight percent, about 0.2 weight percent, about 0.3 weight percent, about 0.4 weight percent, about 0.5 weight percent, about 0.6 weight percent, about 0.7 weight percent, about 0.8 weight percent, about 0.9 weight percent), 1 weight percent), about 2 weight percent, about 3 weight percent, about 4 weight percent, about 5 weight percent, about 6 weight percent, about 7 weight percent), about 8 weight percent), about 9 weight percent, about 10 weight percent, about 11 weight percent, about 12 weight percent, about 13 weight percent), about 14 weight percent), about 15 weight percent, about 16 weight percent, about 17 weight percent, about 18 weight percent, about 19 weight percent, or about 20 weight percent metal complex of the ink composition.

### Decomposition

In another aspect, the conductive ink compositions of the disclosure are decomposed on a substrate to form a conductive structure on the substrate. In some embodiments, the conductive ink composition is decomposed by heating the reducible metal complex at a temperature of about 270° C. or less. In some embodiments, the conductive ink composition is decomposed by heating the conductive ink composition at a temperature of about 260° C. or less, about 250° C. or less, about 240° C. or less, about 230° C. or less, about 220° C. or less, about 210° C. or less, about 200° C. or less, about 190° C. or less, about 180° C. or less, about 170° C. or less, about 160° C. or less, about 150° C. or less, about 140° C. or less, about 130° C. or less, about 120° C. or less, about 110° C. or less, about 100° C. or less, about 90° C. or less, about 80° C. or less, or about 70° C. or less. In some embodiments, the conductive ink composition is heated by a heat source. Examples of heat sources include an IR lamp, oven, or a heated substrate.

In some embodiments, the conductive ink composition is decomposed by exposing the composition to a light source at a wavelength from about 100 nm to about 1500 nm. In some embodiments, the conductive ink composition is decomposed by exposing the composition to a light source such as a Xenon lamp or IR lamp at a wavelength from about 100 nm to about 1000 nm. In some embodiments, the conductive ink composition is decomposed by exposing the composition to a light source at a wavelength from about 100 nm to about 700 nm. In some embodiments, the conductive ink composition is decomposed by exposing the composition to a light source at a wavelength from about 100 nm to about 500 nm. In some embodiments, the conductive ink composition is decomposed by exposing the composition to a light source at a wavelength from about 100 nm to about 300 nm. In some embodiments, the conductive ink composition is decomposed by exposing the composition to a light source at a wavelength of about 100 nm, about 200 nm, about 300 nm, about 400 nm, about 500 nm, about 600 nm, about 700 nm, about 800 nm, about 900 nm, or about 1000 nm.

In some embodiments, the conductive ink composition is decomposed by a combination of heating the reducible metal complex, for example at any of the above-listed temperatures, and exposing the composition to a light source, for example at any of the above-listed wavelengths.

In some embodiments, the electrical conductivity of the conductive structures is measured. In some embodiments, the electrical conductivity of the conductive structures is about 1×10⁻⁶ Ohm-cm or greater. In some embodiments, the electrical conductivity of the conductive structures is from about 1×10⁻⁶ Ohm-cm to about 8×10⁻⁴ Ohm-cm. In some embodiments, the electrical conductivity of the conductive structures is from about 3×10⁻⁶ Ohm-cm to about 6×10⁻⁶ Ohm-cm. In some embodiments, the electrical conductivity of the conductive structures is at least about 1×10⁻⁶ Ohm-cm, about 2×10⁻⁶ Ohm-cm, about 3×10⁻⁶ Ohm-cm, about 4×10⁻⁶ Ohm-cm, about 5×10⁻⁶ Ohm-cm, about 6×10⁻⁶ Ohm-cm, about 7×10⁻⁶ Ohm-cm, about 8×10⁻⁶ Ohm-cm, about 9×10⁻⁶ Ohm-cm, about 1×10⁻⁵ Ohm-cm, about 2×10⁻⁵ Ohm-cm, about 3×10⁻⁵ Ohm-cm, about 4×10⁻⁵ Ohm-cm, about 5×10⁻⁵ Ohm-cm, about 6×10⁻⁵ Ohm-cm, about 7×10⁻⁵ Ohm-cm, about 8×10⁻⁵ Ohm-cm, about 9×10⁻⁵ Ohm-cm, about 1×10⁻⁴ Ohm-cm, about 2×10⁻⁴ Ohm-cm, about 3×10⁻⁴ Ohm-cm, about 4×10⁻⁴ Ohm-cm, about 5×10⁻⁴ Ohm-cm, about 6×10⁻⁴ Ohm-cm, or about 7×10⁻⁴ Ohm-cm. In some embodiments, the electrical conductivity of the conductive structures is at most about 8×10⁻⁴ Ohm-cm, 7×10⁻⁴ Ohm-cm, about 6×10⁻⁴ Ohm-cm, about 5×10⁻⁴ Ohm-cm, about 4×10⁻⁴ Ohm-cm, about 3×10⁻⁴ Ohm-cm, about 2×10⁻⁴ Ohm-cm, or about 1×10⁻⁴ Ohm-cm, about 9×10⁻⁵ Ohm-cm, about 8×10⁻⁵ Ohm-cm, about 7×10⁻⁵ Ohm-cm, about 6×10⁻⁵ Ohm-cm, about 5×10⁻⁵ Ohm-cm, about 4×10⁻⁵ Ohm-cm, about 3×10⁻⁵ Ohm-cm, about 2×10⁻⁵ Ohm-cm, about 1×10⁻⁵ Ohm-cm, about 9×10⁻⁶ Ohm-cm, about 8×10⁻⁶ Ohm-cm, about 7×10⁻⁶ Ohm-cm, about 6×10⁻⁶ Ohm-cm, about 5×10⁻⁶ Ohm-cm, about 4×10⁻⁶ Ohm-cm, about 3×10⁻⁶ Ohm-cm, or about 2×10⁻⁶ Ohm-cm.

It will be readily apparent to one of ordinary skill in the relevant arts that other suitable modifications and adaptations to the compositions and methods described herein may be made without departing from the scope of the invention or any embodiment thereof. Having now described the present invention in detail, the same will be more clearly understood by reference to the following Examples, which are included herewith for purposes of illustration only and are not intended to be limiting of the invention.

### EXAMPLES

### Preparation of Silver Decanoate

The decanoic acid used to form the silver carboxylates of the instant improved conductive ink compositions preferably comprises at least one α-branched decanoic acid isomer. The decanoic acid can be converted to a silver decanoate for use in the conductive ink compositions according to the following general protocol:

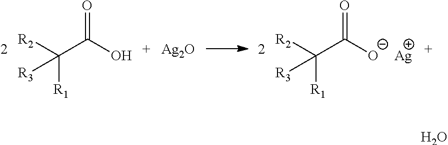

In the above structures, R₁ and R₂ is each independently an alkyl group, wherein R₃ is either hydrogen or an alkyl group, and wherein R₁, R₂, and R₃ together comprise eight total carbon atoms.

In one exemplary preparation of a silver decanoate isomer mixture, Ag₂O powder (13.58 g, 0.058 mol) was slowly added to a solution of a mixture of decanoic acid isomers (21.20 g, 0.12 mol) in dry THF (175 mL) and stirred at room temperature. After 3 hours, the black silver oxide dissolved to form a grey-white solution. The mixture continued to stir overnight until it became a creamy white solution. On completion, methanol (600 mL) was poured into the mixture to precipitate silver decanoate. The solvent was removed and more methanol (600 mL) was added to remove excess decanoic acids. Finally, excess methanol was removed and silver decanoate was collected by centrifugation (20 g, 60%) as a white solid.

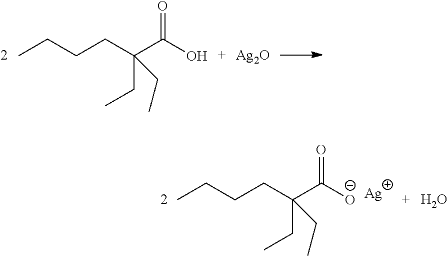

In another exemplary preparation of a silver decanoate, Ag₂O powder (3.01 g, 0.013 mol) was slowly added to a solution of 2,2-diethylhexanoic acid (5.000 g, 0.029 mol) in dry THF (45 mL) and stirred at room temperature. After 24 hrs, the black silver oxide dissolved to form a grey-white solution. The mixture was stirred for another 24 hrs until it became a creamy white solution. On completion, methanol (200 mL) was poured into the mixture to precipitate silver-2,2-diethyl hexanoate (Ag-2,2-DEHA). The solvent was removed and more methanol (200 mL) was added to remove excess 2,2-diethylhexanoic acid. Finally, excess methanol was removed and Ag-2,2-DEHA was collected by centrifugation (1.74 g, 21%) as a white solid.

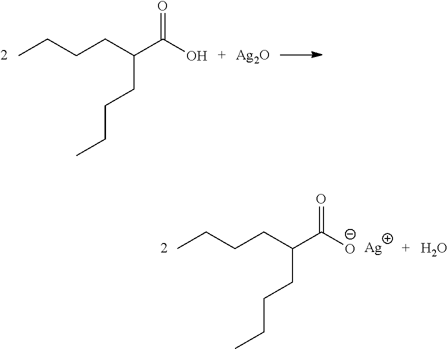

In yet another exemplary preparation of a silver decanoate, Ag₂O powder (3.01 g, 0.013 mol) was slowly added to a solution of 2-butylhexanoic acid (5.000 g, 0.029 mol) in dry THF (45 mL) and stirred at room temperature. After 48 hrs, the black silver oxide dissolved to form a grey-white solution. The mixture was stirred for another 24 hrs until it became a creamy white solution. On completion, methanol (200 mL) was poured into the mixture to precipitate silver-2-butylhexanoate (Ag-2-BHA). The solvent was removed and more methanol (200 mL) was added to remove excess 2-butylhexanoic acid. Finally, excess methanol was removed and Ag-2-BHA was collected by centrifugation (3.4 g, 42%) as a white solid.

### Exemplary Ink Formulations Comprising Silver Decanoate and Their Curing Profiles Formulation 1

In one exemplary ink preparation, 0.720 g silver decanoate isomer mixture (36 wt %) was dissolved in a mixture of 0.509 g of xylene and 0.580 g of α-terpineol. 0.191 g of iso-butanol was added to the mixture, which was then stirred overnight at room temperature. The following day, the mixture was filtered with a 0.45-micron syringe filter to give a colorless solution with a viscosity of 9-11 centipoise.

Upon blade coating the silver ink on glass and polyimide, the ink was annealed at different temperatures from 140° C. to 250° C. for 1 hour in an oven or on a hotplate. After approximately 10 to 15 minutes of curing, the film begins to turn reddish-brown. After approximately 30 minutes, the film begins to turn black and then change to a metallic silver color, thereby denoting the entire complex has decomposed to a metallic, conductive structure.

The conductive structure has an electrical resistance from 0.061 to 0.468 ohms/square (OPS) depending on the substrate and the curing temperature. The results are summarized as follows:

TABLE 1

| | | Resistance on Glass | | Resistance on PI |
|---|---|---|---|---|
| Temperature | Time | (OPS) | | (OPS) |
| (° C.) | (min) | Oven | Hotplate | Oven |
| 140 | 60 | 0.207 | 0.152 | 0.468 |
| 180 | 30 | 0.061 | 0.192 | 0.172 |
| 250 | 20 | 0.138 | 0.112 | 0.183 |

Upon inkjet printing the silver ink on glass, the ink was annealed at different temperatures from 120° C. to 200° C. for 1 hour in an oven. The conductive structure has an electrical resistance from 114.9 to 10.7 (2 and bulk silver levels from 0.87 to 28.98%, depending on the curing temperature. The results are summarized as follows:

TABLE 2

| Temperature | Resistance | Cross Section | |
|---|---|---|---|
| (° C.) | (Ω) | Area (μm²) | Bulk Silver % |
| 120 | 114.9 | 797 | 0.87 |
| 140 | 14.4 | 302 | 18.40 |
| 160 | 14.4 | 287 | 19.36 |
| 180 | 12.7 | 245 | 25.71 |
| 200 | 10.7 | 258 | 28.98 |

(Parameters: 30 μm drop space, 4 layers, 5 cm long lines, 12 pixels)

### Formulation 2

In another exemplary ink preparation, 0.720 g silver decanoate isomer mixture (36 wt %) was dissolved in a mixture of 1.022 g of xylene. 0.258 g of acetylacetone was added to the mixture, which was then stirred overnight at room temperature. The following day, the mixture was filtered with a 0.45-micron syringe filter to give a colorless solution with a viscosity of 3-4 centipoise.

Upon blade coating the silver ink on glass and polyimide, the ink was annealed at different temperatures from 140 C to 250° C. for 1 hour in an oven or on a hotplate. After approximately 10 to 15 minutes of curing, the film begins to turn reddish-brown. After approximately 30 minutes, the film begins to turn black and then change to a metallic silver color, thereby denoting the entire complex has decomposed to a metallic, conductive structure.

The conductive structure has an electrical resistance from 0.101 to 0.962 ohms/square (OPS) depending on the substrate and the curing temperature. The results are summarized as follows:

TABLE 3

| | | Resistance on Glass | | Resistance on PI |
|---|---|---|---|---|
| Temperature | Time | (OPS) | | (OPS) |
| (° C.) | (min) | Oven | Hotplate | Oven |
| 140 | 60 | 0.295 | 0.108 | 0.962 |
| 180 | 30 | 0.242 | 0.114 | 0.221 |
| 250 | 20 | 0.576 | 0.101 | 0.231 |

### Formulation 3

In yet another exemplary ink preparation, 0.720 g silver 2,2-diethylhexanoate (18.5 wt %) was dissolved in a mixture of 2.397 g of xylene and 0.580 g of α-terpineol. 0.191 g of iso-butanol was added to the mixture, which was then stirred overnight at room temperature. The following day, the mixture was filtered with a 0.45-micron syringe filter to give a colorless solution.

Upon inkjet printing the silver ink on glass, the ink was annealed at different temperatures from 120° C. to 180° C. for 1 hour in an oven. The conductive structure has an electrical resistance and bulk conductivity range from 91.5 to 21.6Ω and bulk silver levels from 2.45 to 19.49%, depending on the curing temperature. The results are summarized as follows:

TABLE 4

| Temperature | Resistance | Cross section | |
|---|---|---|---|
| (° C.) | (Ω) | area (μm²) | Bulk Silver ( % ) |
| 120 | 91.5 | 357 | 2.45 |
| 140 | 40.7 | 237 | 8.29 |
| 160 | 28.3 | 221 | 12.79 |
| 180 | 21.6 | 190 | 19.49 |

(Parameters: 30 μm drop space, 8 layers, 5 cm long lines, 12 pixels)

### Formulation 4

In still yet another exemplary ink preparation, 0.720 g silver decanoate isomer mixture (18.5 wt %) was dissolved in a mixture of 2.397 g of xylene and 0.580 g of α-terpineol. 0.191 g of iso-butanol was added to the mixture, which was then stirred overnight at room temperature. The following day, the mixture was filtered with a 0.45-micron syringe filter to give a colorless solution.

Upon inkjet printing the silver ink on glass, the ink was annealed at different temperatures from 120° C. to 200° C. for 1 hour in an oven. The conductive structure has an electrical resistance and bulk conductivity range from 644 to 9.9Ω and bulk silver levels from 0.09 to 36.08%, depending on the curing temperature. The results are summarized as follows.

TABLE 5

| Temperature | Resistance | Cross Section | |
|---|---|---|---|
| (° C.) | (Ω) | Area (μm²) | Bulk Silver % |
| 120 | 644.0 | 1397 | 0.09 |
| 140 | 22.1 | 269 | 13.46 |
| 160 | 19.0 | 248 | 16.98 |
| 180 | 15.0 | 286 | 18.65 |
| 200 | 9.9 | 224 | 36.08 |

(Parameters: 30 μm drop space, 8 layers, 5 cm long lines, 12 pixels)

Conductive Ink Formulations comprising Nonaromatic Dissolving Agents Formulation 5

36% silver decanoate isomer mixture in 64% limonene with post-addition of 1.5% decanoic acid isomer mixture.

### Formulation 6

45% silver decanoate isomer mixture in 55% limonene with post-addition of 1.5% decanoic acid isomer mixture.

### Formulation 7

45% silver decanoate isomer mixture in 55% limonene with post-addition of 3% decanoic acid isomer mixture.

### Formulation 8

40% silver decanoate isomer mixture in 50% limonene and 10% terpineol with post-addition of 3% decanoic acid isomer mixture.

### Formulation 9

36% silver decanoate isomer mixture in 44% limonene and 20% terpineol with post-addition of 3% decanoic acid isomer mixture.

### Formulation 10

50% silver decanoate isomer mixture in 45% xylene and 5% terpineol. (Used as control for comparison with nonaromatic dissolving agents.)

### Formulation 11

36% silver decanoate isomer mixture in 32% terpineol and 32% limonene with post-addition of 1.5% decanoic acid isomer mixture.

### Formulation 12

36% silver decanoate isomer mixture in 32% terpineol and 32% limonene with post-addition of 1.5% decanoic acid isomer mixture and 0.5% Triethoxysilyl modified Poly-1,2-Butadiene, 50% in volatile silicone (SSP056) (available from Gelest).

### Formulation 13

36% silver decanoate isomer mixture in 32% terpineol and 32% limonene with post-addition of 3% decanoic acid isomer mixture and 0.5% Triethoxysilyl modified Poly-1,2-Butadiene, 50% in volatile silicone (SSP056).

### Formulation 14

45% silver decanoate isomer mixture in 55% limonene with post-addition of 3% decanoic acid isomer mixture and 0.5% Triethoxysilyl modified Poly-1,2-Butadiene, 50% in volatile silicone (SSP056).

TABLE 6
Summary of representative conductive ink formulations containing nonaromatic
solvents

| | Formulation 1 | | | | |
|---|---|---|---|---|---|
| | (control) | Formulation 5 | Formulation 6 | Formulation 7 | Formulation 13 |
| Silver Content | 14% | 14% | 17% | 17% | 14% |
| pH | — | — | — | — | — |
| Viscosity | 10 | 4 | 6.1 | 6.1 | 16.5 |
| 25C (cP) | | | | | |
| Stability at 40° C. | >20 days | >20 | ~7 days | >20 days | >20 days |
| storage | | | | | |
| Samba Inkjet | − | + | + | + | + |
| jetting | | | | | |

In situ Thermal Curing of Conductive Ink Formulations with Nonaromatic Dissolving Agents

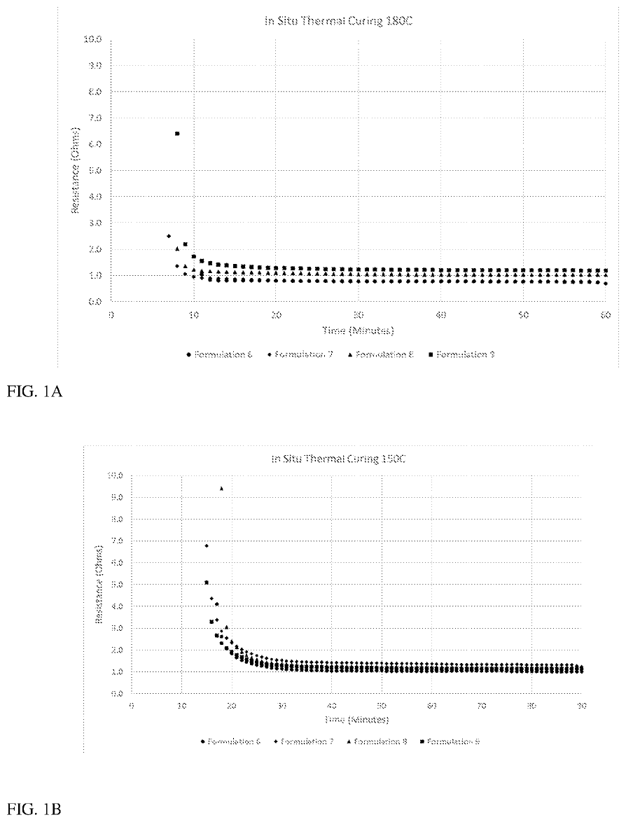

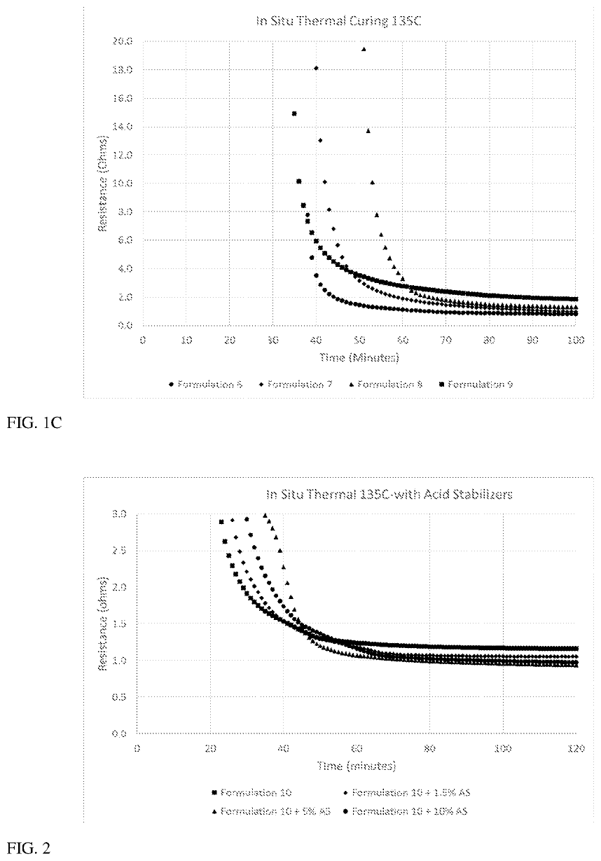

FIGS. 1A-1C show the time course for in situ thermal curing of conductive inks containing nonaromatic dissolving agents at different temperatures. The electrical properties of the conductive silver structures formed from the conductive inks at various temperatures are summarized below:

TABLE 7
Electrical properties of silver structures formed at different temperatures

| | Curing | Formulation | Formulation | Formulation | Formulation | Formulation |
|---|---|---|---|---|---|---|
| | Temperature | 6 | 7 | 8 | 9 | 13 |
| Resistance | 135° C. | 0.56 | 0.67 | 0.76 | 1.1 | |
| (ohms) | | | | | | |
| Cross- | 135° C. | 2571 | 2234 | 2100 | 1380 | |
| section | | | | | | |
| (μm²) | | | | | | |
| Resistivity | 135° C. | 5.8 | 6.0 | 6.4 | 6.1 | |
| (μohm- | | | | | | |
| cm) | | | | | | |
| Resistance | 150° C. | 0.55 | 0.8 | 0.63 | 0.71 | |
| (ohms) | | | | | | |
| Cross- | 150° C. | 1955 | 1434 | 1591 | 1640 | |
| section | | | | | | |
| (μm²) | | | | | | |
| Resistivity | 150° C. | 4.3 | 4.6 | 5.2 | 4.7 | 8 |
| (μohm- | | | | | | |
| cm) | | | | | | |
| Resistance | 180° C. | 0.48 | 0.48 | 0.63 | 0.69 | |
| (ohms) | | | | | | |
| Cross- | 180° C. | 2183 | 2206 | 1591 | 1558 | |
| section | | | | | | |
| (μm²) | | | | | | |
| Resistivity | 180° C. | 4.2 | 4.6 | 4 | 4.3 | 6.1 |
| (μohm- | | | | | | |
| cm) | | | | | | |

In situ Thermal Curing of Conductive Ink Formulations with an Acid Stabilizer

FIG. 2 shows the time course for in situ thermal curing of a novel conductive ink formulation containing increasing amounts of an α-branched decanoic acid stabilizer (AS) at 135° C. All of the conductive silver structures formed from the conductive inks cure in a similar time and display similar resistivities (4.4. to 5 μOhm-cm).

In situ Thermal Curing of Conductive Ink Formulations with an Adhesion Promoter

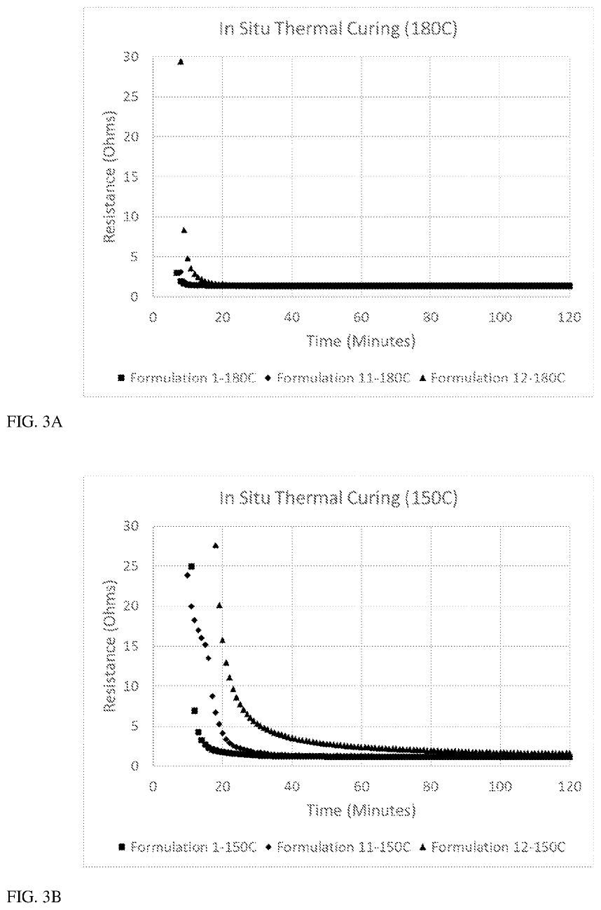

FIGS. 3A and 3B show the time course for in situ thermal curing of a novel conductive ink formulation with (Formulation 12) and without (Formulation 11) a reactive silane adhesion promoter (SSP056) at 180° C. (FIG. 3A) and at 150° C. (FIG. 3B). The formulations also included a 1.5% decanoic acid isomer mixture as an acid stabilizer. Formulation 1 was included as a control.

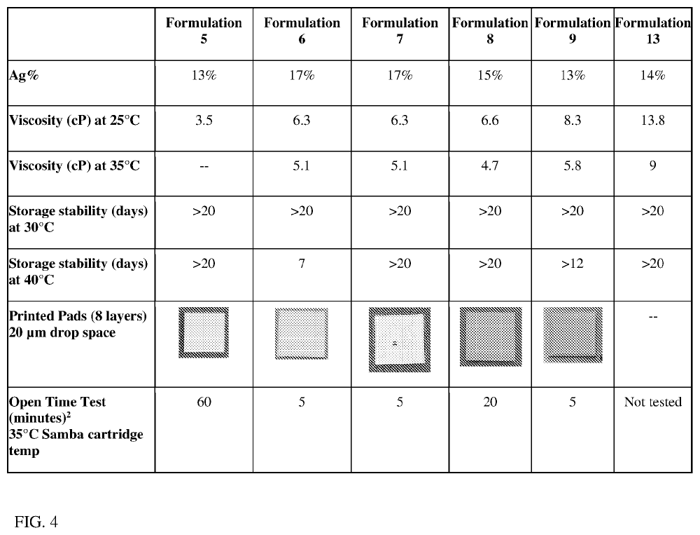

FIG. 4 summarizes various features and properties of representative ink formulations containing non-aromatic solvents. The images of printed pads provide a metric for ink coating quality. An inkjet pad is printed with each ink to see the spreading or beading up nature of the print on a specific substrate. Glass substrates were used in these examples. Open time is a metric in inkjet printing. Volatile inks typically evaporate at the nozzle after a measured amount of open time (where open time is the time the printer is left sitting stagnant without printing). The evaporation of the ink can cause the jet to stop working.

Exemplary Ink Formulations Comprising (3-glycidyloxypropyl) trimethoxysilane and Their Stability and Curing Profiles

### Formulation 15

36% silver decanoate isomer mixture in 32% terpineol and 32% limonene with post-addition of 3% decanoic acid isomer mixture and 0.5% (3-glycidyloxypropyl) trimethoxysilane as adhesion promoter.

### Formulation 16

45% silver decanoate isomer mixture in 55% limonene with post-addition of 3% decanoic acid isomer mixture and 0.5% (3-glycidyloxypropyl) trimethoxysilane as adhesion promoter.

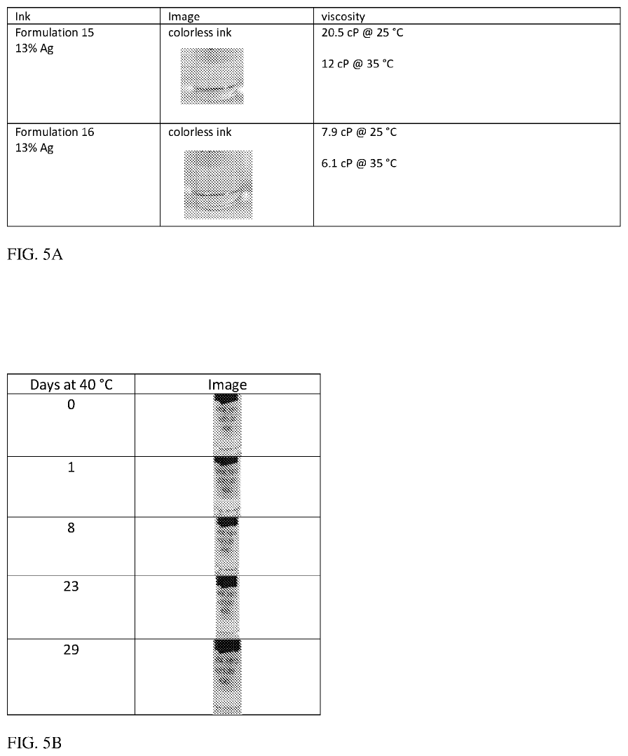

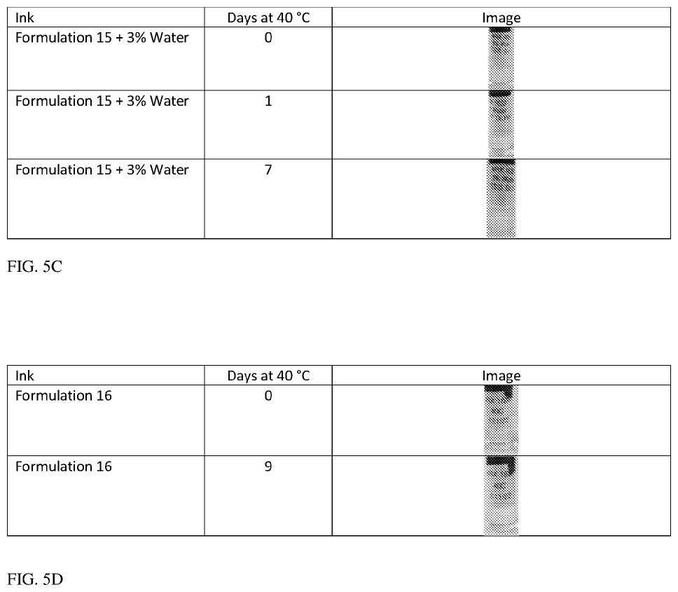

FIG. 5A shows images of Formulations 15 and 16 in glass vials. These formulations result in clear, colorless ink solutions with the indicated silver content and viscosities.

FIG. 5B shows the stability of Formulation 15 at elevated temperature. Images of a glass vial containing this formulation show that the ink remains clear and colorless for at least 29 days at 40° C.

FIG. 5C shows the stability of Formulation 15 with 3% added water at elevated temperature. Images of a glass vial containing this formulation show that the ink remains clear and colorless for at least 7 days at 40° C.

FIG. 5D shows the stability of Formulation 16 at elevated temperature. Images of a glass vial containing this formulation show that the ink remains clear and colorless for at least 9 days at 40° C.

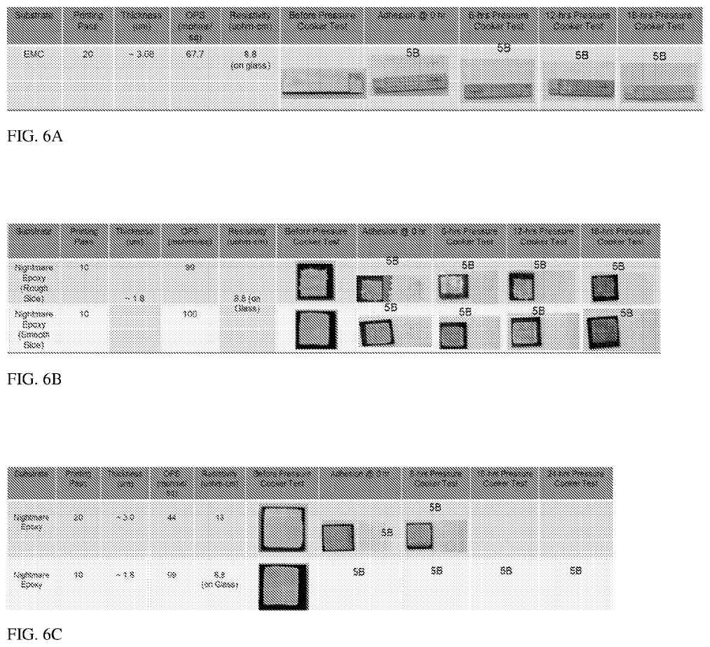

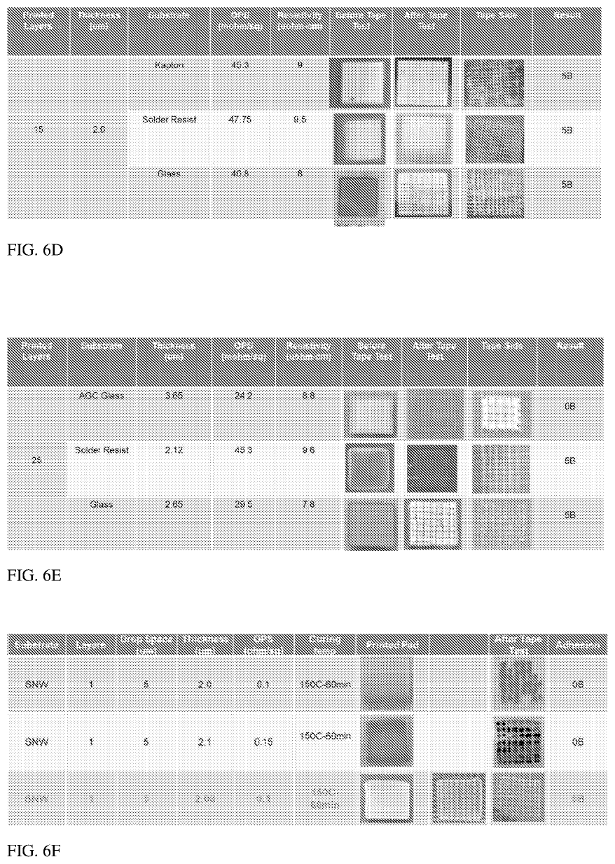

FIGS. 6A-6F show exemplary conductive structures printed using the disclosed conductive ink formulations on various test substrates.

FIG. 6A shows the results of printing Formulation 15 on a regular EMC substrate, with the indicated printing passes, thickness of the printed structure, sheet resistance, and resistivity. Also shown are images of the printed structure formed from this ink over time under a pressure cooker test.

FIG. 6B shows the results of printing Formulation 15 on each side of an alternative EMC substrate (with residual mold release on the surface) to 1.8 μm thickness only, with the indicated printing passes, thickness of the printed structure, sheet resistance, and resistivity. Also shown are images of the printed structure formed from this ink over time under a pressure cooker test.

FIG. 6C shows the results of printing Formulation 15 on each side of an alternative EMC substrate (with residual mold release on the surface) to 1.8 μm and 3.0 μm thicknesses, with the indicated printing passes, thickness of the printed structure, sheet resistance, and resistivity. Also shown are images of the printed structure formed from this ink over time under a pressure cooker test.

FIG. 6D shows the results of printing thin films of Formulation 16 on various substrates, with the indicated printed layers, thickness of the printed structure, sheet resistance, and resistivity. Also shown are images of the printed structure formed from this ink before and after a tape test.

FIG. 6E shows the results of printing thick films of Formulation 16 on various substrates, with the indicated printed layers, thickness of the printed structure, sheet resistance, and resistivity. Also shown are images of the printed structure formed from this ink before and after a tape test.

FIG. 6F shows a comparison of printing Formulation 16 (bottom row) with Formulation 7 (top row) and Formulation 14 (middle row) on a silver nanowire (SNW) substrate. As is clear from the results of a tape test, the conductive structure prepared using an ink composition comprising the (3-glycidyloxypropyl) trimethoxysilane adhesion promoter (Formulation 16) has significantly improved adhesion properties compared to a structure prepared from an ink composition lacking an adhesion promoter (Formulation 7) and a structure prepared from an ink composition comprising a Triethoxysilyl modified Poly-1,2-Butadiene (SSP056) adhesion promoter (Formulation 14).

Exemplary Ink Formulations Comprising (3-glycidyloxypropyl)triethoxysilane and Their Stability and Curing Profiles

### Formulation 17

45% silver decanoate isomer mixture in 55% limonene with post-addition of 3% decanoic acid isomer mixture and 0.5% (3-glycidyloxypropyl)triethoxysilane as adhesion promoter.

### Formulation 18

36% silver decanoate isomer mixture in 32% terpineol and 32% limonene with post-addition of 3% decanoic acid isomer mixture and 0.5% (3-glycidyloxypropyl)triethoxysilane as adhesion promoter.

### Formulation 19

45% silver decanoate isomer mixture in 55% limonene with post-addition of 3% 2,2,6,6-tetramethyl-3,5-heptanedione as stabilizer and 1.5% (glycidyloxypropyl)triethoxysilane as adhesion promoter.

Formulations 17, 18, and 19 result in clear, colorless ink compositions comprising 13% silver. Formulations 18 and 19 are held at 40° for at least one week to assess their stability.

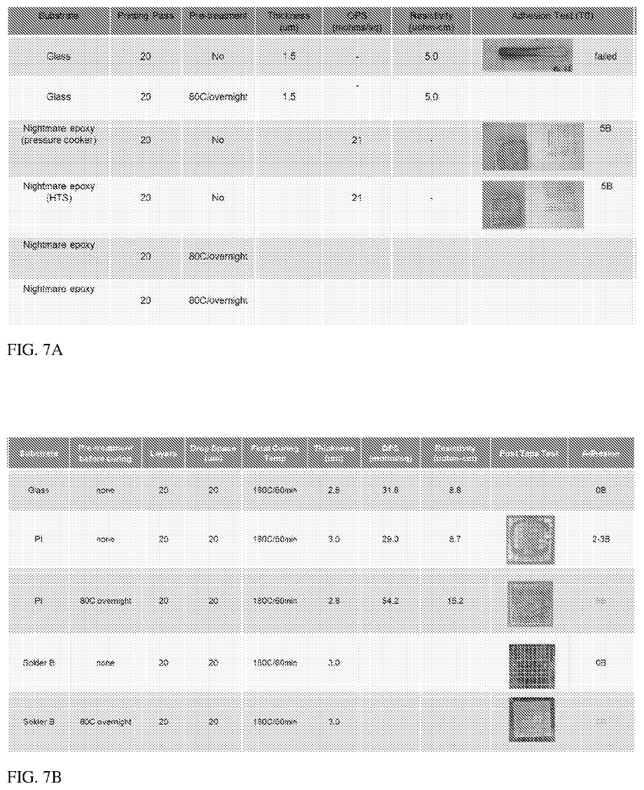

FIG. 7A illustrates the results of printing Formulation 18 on different substrates under different conditions.

FIG. 7B illustrates the results of printing Formulation 19 on different substrates under different conditions.

### Exemplary Ink Formulations Comprising Dendrimeric Adhesion Promoters and Their Stability and Curing Profiles

### Formulation 20

36% silver decanoate isomer mixture in 32% terpineol and 32% limonene with post-addition of 3% decanoic acid isomer mixture and 1.5% PAMAM Dendrimer G2-50% C12 mixed amine/hydrophobe as adhesion promoter.

### Formulation 21

36% silver decanoate isomer mixture in 32% terpineol and 32% limonene with post-addition of 3% 2,2,6,6-tetramethyl-3,5-heptanedione as stabilizer and 1.5% PAMAM Dendrimer G2-50% C12 mixed amine/hydrophobe as adhesion promoter.

### Formulation 22

36% silver decanoate isomer mixture in 32% terpineol and 32% limonene with post-addition of 1% 2,2,6,6-tetramethyl-3,5-heptanedione and 3% decanoic acid isomer mixture as stabilizers and 1.5% PAMAM Dendrimer G2-50% C12 mixed amine/hydrophobe as adhesion promoter.

Formulations 20, 21, and 22 all result in clear, colorless ink compositions that comprise 13.5% silver.

The novel dendrimer-containing conductive ink formulations have been characterized using standard techniques in the art.

FIG. 8 shows the physical and electrical properties of conductive structures prepared by printing Formulations 21 and 22 on EMC substrates.

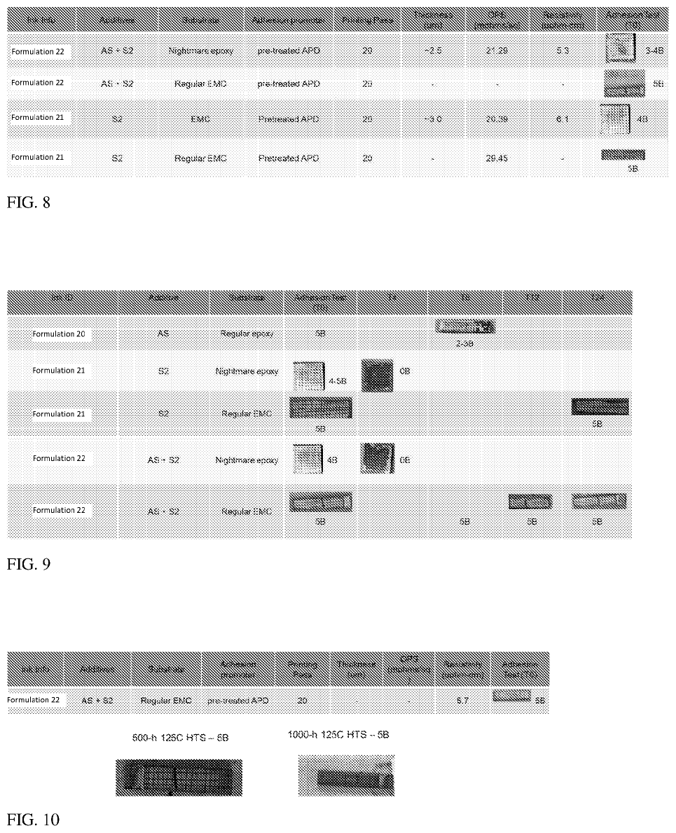

FIG. 9 shows the stability of conductive structures prepared from Formulations 20, 21, and 22 over time in a pressure cooker test.

FIG. 10 shows high temperature storage (HTS) testing of conductive structures prepared from Formulation 22 at 125° C. for 500 and 1000 hours.

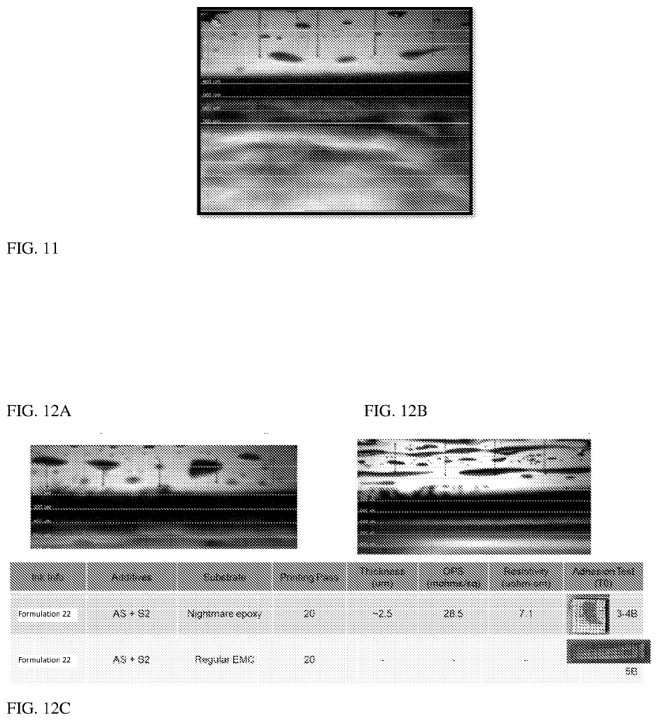

FIG. 11 is an image of an inkjet printer nozzle plate in the process of printing a fresh preparation of Formulation 22. This conductive ink formulation achieved stable printing without nozzle clogging or plate wetting.

FIGS. 12A and 12B are images of an inkjet printer nozzle plate in the process of printing preparations of Formulation 22 that had been stored at 4° C. for either 20 days in the printer cartridge (FIG. 12A) or 8 days in a vial (FIG. 12B). FIG. 12C shows the physical and electrical properties of conductive structures prepared using this ink formulation on two different substrates.

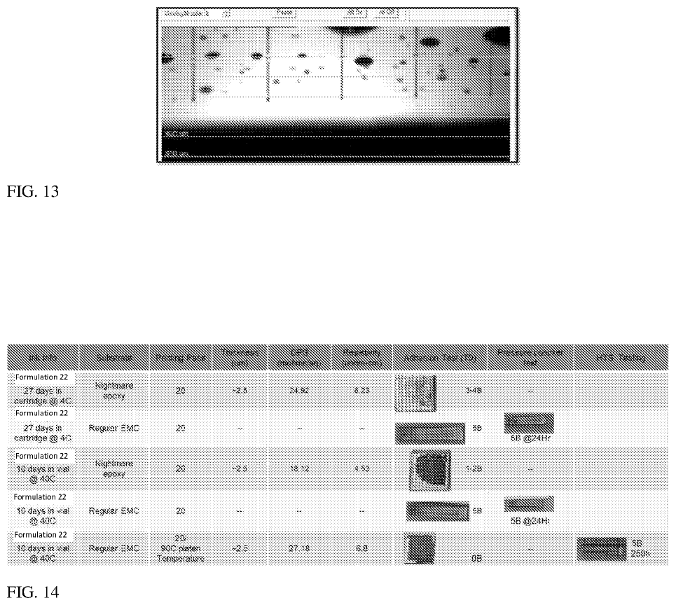

FIG. 13 shows an image of an inkjet printer nozzle plate in the process of printing a preparation of Formulation 22 that had been stored at 40° C. for 10 days in a vial.

FIG. 14 shows the properties of conductive structures prepared on different substrates using Formulation 22 that had been stored either at 4° C. in a cartridge for 27 days or at 40° C. in a vial for 10 days.

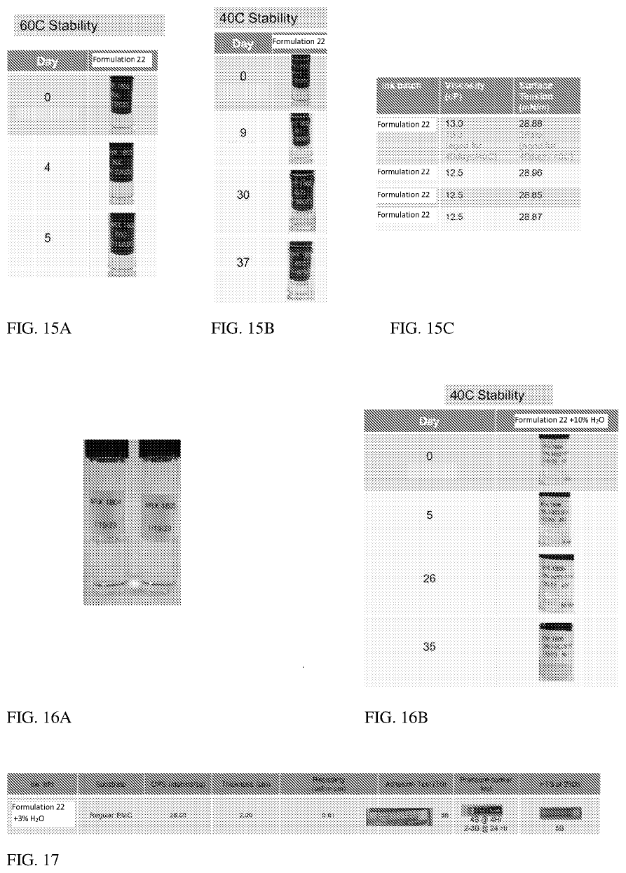

FIGS. 15A and 15B illustrate the stability of Formulation 22 over time at 60° C. and 40° C., respectively. FIG. 15C shows the viscosity and surface tension for different batches of Formulation 22.

Formulation 22 was further treated with various amounts of water to test stability of the formulations under storage conditions at low and high temperatures. The effect of water on the physical and electrical properties of conductive structures prepared from treated ink formulations was also assessed.

FIG. 16A shows the stability of Formulation 22 spiked with 1.5% H₂O (left vial) and 10% H₂O (right vial) at 4° C. No polymerization was observed in either vial for at least 35 days. FIG. 16B shows the stability of Formulation 22 spiked with 10% H₂O over time at 40° C.

FIG. 17 shows reliability testing of conductive structures prepared using Formulation 22 spiked with 3% H₂O.

All patents, patent publications, and other published references mentioned herein are hereby incorporated by reference in their entireties as if each had been individually and specifically incorporated by reference herein.

While specific examples have been provided, the above description is illustrative and not restrictive. Any one or more of the features of the previously described embodiments can be combined in any manner with one or more features of any other embodiments in the present invention. Furthermore, many variations of the invention will become apparent to those skilled in the art upon review of the specification. The scope of the invention should, therefore, be determined by reference to the appended claims, along with their full scope of equivalents.

What is claimed is:

1. A conductive ink composition comprising a silver complex formed by combining:
a silver decanoate; and
at least one dissolving agent;
wherein the at least one dissolving agent comprises a terpene, a terpenoid, or a combination thereof; and
wherein the silver decanoate is decarboxylated at a temperature of 250° C. or less to form a conductive structure.

2. The conductive ink composition of claim 1, wherein the silver decanoate comprises at least one α-branched silver decanoate isomer.

3. The conductive ink composition of claim 1, wherein the silver decanoate comprises a plurality of α-branched silver decanoate isomers.

4. The conductive ink composition of claim 1, wherein the silver decanoate has a structure: 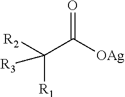
wherein R₁ and R₂ is each independently an alkyl group, wherein R₃ is either hydrogen or an alkyl group, and wherein R₁, R₂, and R₃ together comprise eight total carbon atoms.

5. The conductive ink composition of claim 4, wherein R₁ and R₂ is each independently methyl or ethyl.

6. The conductive ink composition of claim 4, wherein the silver decanoate comprises silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or a combination thereof.

7. The conductive ink composition of claim 1, wherein the conductive ink composition is particle free.

8. The conductive ink composition of claim 1, wherein the terpene is a purified terpene or the terpenoid is a purified terpenoid.

9. The conductive ink composition of claim 1, wherein the terpene is a pinene or a limonene.

10. The conductive ink composition of claim 1, wherein the terpenoid is a terpineol.

11. The conductive ink composition of claim 1, wherein the at least one dissolving agent comprises a limonene and a terpineol.

12. The conductive ink composition of claim 11, wherein the limonene is a purified limonene and the terpineol is a purified terpineol.

13. The conductive ink composition of claim 1, further comprising an adhesion promoter.

14. The conductive ink composition of claim 13, wherein the adhesion promoter comprises a reactive silane.

15. The conductive ink composition of claim 14, wherein the adhesion promoter comprises an alkoxysilane.

16. The conductive ink composition of claim 15, wherein the adhesion promoter comprises an ethoxysilyl modified polyalkene.

17. The conductive ink composition of claim 16, wherein the adhesion promoter comprises a triethoxysilyl modified poly-1,2-butadiene.

18. The conductive ink composition of claim 13, wherein the adhesion promoter is a structure of formula I: 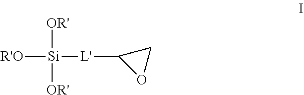
wherein each R′ is independently a C₁-C₆ alkyl group, and L′ is an alkyl linker group.

19. The conductive ink composition of claim 18, wherein the adhesion promoter is:

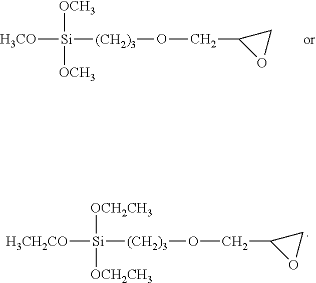

20. The conductive ink composition of claim 13, wherein the adhesion promoter comprises a dendrimeric compound.

21. The conductive ink composition of claim 20, wherein the dendrimeric compound is a poly(amidoamine) dendrimeric compound.

22. The conductive ink composition of claim 21, wherein the poly(amidoamine) dendrimeric compound is a generation 2 poly(amidoamine) dendrimeric compound.

23. The conductive ink composition of claim 21, wherein the poly(amidoamine) dendrimeric compound is a hydrophobe substituted poly(amidoamine) dendrimeric compound.

24. The conductive ink composition of claim 23, wherein the poly(amidoamine) dendrimeric compound is substituted with a C12 hydrophobe.

25. The conductive ink composition of claim 1, further comprising an acid stabilizer.

26. The conductive ink composition of claim 25, wherein the acid stabilizer is a C₆₋₁₂ α-branched alkanoic acid.

27. The conductive ink composition of claim 26, wherein the acid stabilizer is an α-branched decanoic acid isomer.

28. The conductive ink composition of claim 27, wherein the acid stabilizer is 2,2-dimethylhexanoic acid or 2,2-dimethylnonanoic acid.

29. The conductive ink composition of claim 1, wherein the silver decanoate comprises at least one α-branched silver decanoate isomer, the at least one dissolving agent comprises a limonene and a terpineol, and the conductive ink composition further comprises an adhesion promoter comprising a reactive silane.

30. The conductive ink composition of claim 29, further comprising an acid stabilizer.

31. The conductive ink composition of claim 1, wherein the silver decanoate comprises at least one α-branched silver decanoate isomer, the at least one dissolving agent comprises a limonene and a terpineol, and the conductive ink composition further comprises an adhesion promoter comprising a dendrimeric compound.

32. The conductive ink composition of claim 31, further comprising an acid stabilizer.

33. The conductive ink composition of claim 1, wherein the silver decanoate comprises at least one α-branched silver decanoate isomer, the at least one dissolving agent comprises a limonene, and the conductive ink composition further comprises an acid stabilizer.

34. The conductive ink composition of claim 1, wherein the conductive ink composition has a concentration of about 1 to about 50 weight percent silver decanoate.

35. The conductive ink composition of claim 1, wherein the conductive ink composition has a viscosity from about 5 centipoise to about 50 centipoise.

36. The conductive ink composition of claim 1, wherein the conductive ink composition has a viscosity from about 50 centipoise to about 1000 centipoise.

37. The conductive ink composition of claim 1, wherein the conductive structure has a resistance of no more than 5 ohms per square, no more than 2 ohms per square, no more than 1 ohm per square, or no more than 0.5 ohms per square.

38. The conductive ink composition of claim 1, wherein the conductive structure has a bulk silver content of at least 1%.

39. The conductive ink composition of claim 1, wherein the silver decanoate is decarboxylated at a temperature of 180° C. or less to form the conductive structure.

40. The conductive ink composition of claim 1, wherein the silver decanoate is decarboxylated at a temperature of 150° C. or less to form the conductive structure.

41. A method of making a conductive ink composition, comprising:
dissolving a silver decanoate in at least one dissolving agent to form a conductive ink composition;
wherein the silver decanoate comprises at least one α-branched silver decanoate isomer and the at least one dissolving agent comprises a terpene, a terpenoid; or a combination thereof.

42. The method of claim 41, wherein the silver decanoate does not comprise silver n-decanoate.

43. The method of claim 41, wherein the conductive ink composition does not comprise a catalyst.

44. The method of claim 41, wherein the conductive ink composition does not comprise a catalyst comprising an amine.

45. The method of claim 41, wherein the conductive ink composition is particle-free.

46. The method of claim 41, wherein the silver decanoate comprises a plurality of α-branched silver decanoate isomers.

47. The method of claim 41, wherein the silver decanoate has a structure: 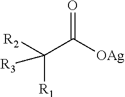
wherein R₁ and R₂ is each independently an alkyl group, wherein R₃ is either hydrogen or an alkyl group, and wherein R₁, R₂, and R₃ together comprise eight total carbon atoms.

48. The method of claim 47, wherein R₁ and R₂ is each independently methyl or ethyl.

49. The method of claim 47, wherein the silver decanoate comprises silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or a combination thereof.

50. The method of claim 41, wherein the terpene is a purified terpene or the terpenoid is a purified terpenoid.

51. The method of claim 41, wherein the terpene is a pinene or a limonene.

52. The method of claim 41, wherein the terpenoid is a terpineol.

53. The method of claim 41, wherein the at least one dissolving agent comprises a limonene and a terpineol.

54. The method of claim 53, wherein the limonene is a purified limonene and the terpineol is a purified terpineol.

55. The method of claim 41, comprising the further step of dissolving an adhesion promoter in the at least one dissolving agent.

56. The method of claim 55, wherein the adhesion promoter comprises a reactive silane.

57. The method of claim 56, wherein the adhesion promoter comprises an alkoxysilane.

58. The method of claim 57, wherein the adhesion promoter comprises an ethoxysilyl modified polyalkene.

59. The method of claim 58, wherein the adhesion promoter comprises a triethoxysilyl modified poly-1,2-butadiene.

60. The method of claim 55, wherein the adhesion promoter is a structure of formula I: 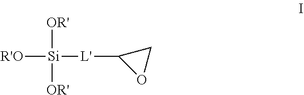
wherein each R′ is independently a C₁-C₆ alkyl group, and L′ is an alkyl linker group.

61. The method of claim 60, wherein the adhesion promoter is:

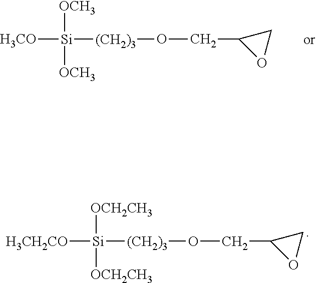

62. The method of claim 55, wherein the adhesion promoter comprises a dendrimeric compound.

63. The method of claim 62, wherein the dendrimeric compound is a poly(amidoamine) dendrimeric compound.

64. The method of claim 63, wherein the poly(amidoamine) dendrimeric compound is a generation 2 poly(amidoamine) dendrimeric compound.

65. The method of claim 63, wherein the poly(amidoamine) dendrimeric compound is a hydrophobe substituted poly(amidoamine) dendrimeric compound.

66. The method of claim 65, wherein the poly(amidoamine) dendrimeric compound is substituted with a C12 hydrophobe.

67. The method of claim 41, comprising the further step of dissolving an acid stabilizer in the at least one dissolving agent.

68. The method of claim 67, wherein the acid stabilizer is a C₆₋₁₂ α-branched alkanoic acid.

69. The method of claim 68, wherein the acid stabilizer is an α-branched decanoic acid isomer.

70. The method of claim 69, wherein the acid stabilizer is 2,2-dimethylhexanoic acid or 2,2-dimethylnonanoic acid.

71. The method of claim 41, wherein the silver decanoate comprises at least one α-branched silver decanoate isomer, the at least one dissolving agent comprises a limonene and a terpineol, and the method comprises a further step of dissolving an adhesion promoter comprising a reactive silane in the at least one dissolving agent.

72. The method of claim 71, comprising the further step of dissolving an acid stabilizer in the at least one dissolving agent.

73. The method of claim 41, wherein the silver decanoate comprises at least one α-branched silver decanoate isomer, the at least one dissolving agent comprises a limonene and a terpineol, and the method comprises a further step of dissolving an adhesion promoter comprising a dendrimeric compound in the at least one dissolving agent.

74. The method of claim 73, comprising the further step of dissolving an acid stabilizer in the at least one dissolving agent.

75. The method of claim 41, wherein the silver decanoate comprises at least one α-branched silver decanoate isomer, the at least one dissolving agent comprises a limonene, and the method comprises a further step of dissolving an acid stabilizer in the at least one dissolving agent.

76. The method of claim 41, wherein the conductive ink composition has a concentration of about 1 to about 50 weight percent silver decanoate.

77. The method of claim 41, wherein the conductive ink composition has a viscosity from about 5 centipoise to about 50 centipoise.

78. The method of claim 41, wherein the conductive ink composition has a viscosity from about 50 centipoise to about 1000 centipoise.

79. The method of claim 41, wherein the silver decanoate is decarboxylated at a temperature of 180° C. or less to form a conductive structure.

80. The method of claim 41, wherein the silver decanoate is decarboxylated at a temperature of 150° C. or less to form a conductive structure.

81. A method of forming a conductive structure, comprising:
applying the conductive ink composition of any one of claims 1-40 to a substrate; and
heating the conductive ink composition on the substrate to a temperature of about 250° C. or less to form the conductive structure.

82. The method of claim 81, wherein the conductive ink composition is applied by slot die coating, spin coating, roll-to-roll printing, including gravure, flexography, rotary screen printing, screen printing, aerosol jet printing, inkjet printing, airbrushing, Mayer rod coating, flood coating, 3D printing, dispenser, or electrohydrodynamic printing.

83. The method of claim 81, wherein the conductive structure has a resistance of no more than 5 ohms per square, no more than 2 ohms per square, no more than 1 ohm per square, or no more than 0.5 ohms per square.

84. The method of claim 81, wherein the conductive structure has a bulk silver content of at least 1%.

85. A conductive ink composition comprising a silver complex formed by combining:
a silver decanoate;
at least one dissolving agent; and
an adhesion promoter, wherein the adhesion promoter comprises a reactive silane or an epoxide or comprises a dendrimeric compound;
wherein the silver decanoate is decarboxylated at a temperature of 250° C. or less to form a conductive structure.

86. The conductive ink composition of claim 85, wherein the silver decanoate comprises at least one α-branched silver decanoate isomer.

87. The conductive ink composition of claim 85, wherein the silver decanoate comprises a plurality of α-branched silver decanoate isomers.

88. The conductive ink composition of claim 85, wherein the silver decanoate has a structure: 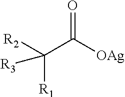
wherein R₁ and R₂ is each independently an alkyl group, wherein R₃ is either hydrogen or an alkyl group, and wherein R₁, R₂, and R₃ together comprise eight total carbon atoms.

89. The conductive ink composition of claim 88, wherein R₁ and R₂ is each independently methyl or ethyl.

90. The conductive ink composition of claim 88, wherein the silver decanoate comprises silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or a combination thereof.

91. The conductive ink composition of claim 85, wherein the conductive ink composition is particle free.

92. The conductive ink composition of claim 85, wherein the at least one dissolving agent comprises a terpene, a terpenoid, or a combination thereof.

93. The conductive ink composition of claim 92, wherein the terpene is a pinene or a limonene.

94. The conductive ink composition of claim 92, wherein the terpenoid is a terpineol.

95. The conductive ink composition of claim 92, wherein the at least one dissolving agent comprises a limonene and a terpineol.

96. The conductive ink composition of claim 95, wherein the limonene is a purified limonene and the terpineol is a purified terpineol.

97. The conductive ink composition of claim 85, wherein the adhesion promoter comprises a reactive silane and an epoxide.

98. The conductive ink composition of claim 97, wherein the adhesion promoter is a structure of formula I: 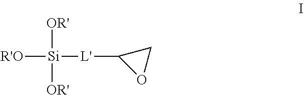
wherein each R′ is independently a C₁-C₆ alkyl group, and L′ is an alkyl linker group.

99. The conductive ink composition of claim 98, wherein each R′ is independently a methyl or an ethyl group.

100. The conductive ink composition of claim 98, wherein L′ is a C₂-C₁₀-alkyl linker group.

101. The conductive ink composition of claim 100, wherein L′ is a substituted C₂-C₁₀-alkyl linker group.

102. The conductive ink composition of claim 101, wherein one or more carbon atoms in L′ is be substituted with a heteroatom.

103. The conductive ink composition of claim 98, wherein the adhesion promoter is a structure of formula II: 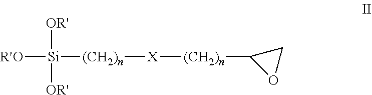
wherein each R′ is independently a methyl or an ethyl group, X is a heteroatom, and each n is independently 1-6.

104. The conductive ink composition of claim 103, wherein each R′ is a methyl group, X is oxygen, and each n is independently 1-3.

105. The conductive ink composition of claim 98, wherein the adhesion promoter is:

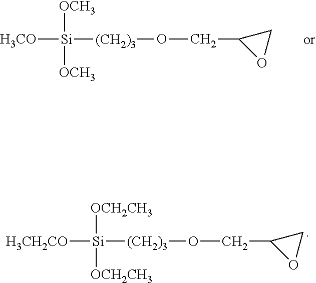

106. The conductive ink composition of claim 97, wherein the adhesion promoter comprises an alkoxysilane.

107. The conductive ink composition of claim 106, wherein the adhesion promoter comprises a methoxysilyl or an ethoxysilyl group.

108. The conductive ink composition of claim 85, wherein the adhesion promoter comprises a poly(amidoamine) dendrimeric compound.

109. The conductive ink composition of claim 108, wherein the poly(amidoamine) dendrimeric compound is a generation 2 poly(amidoamine) dendrimeric compound.

110. The conductive ink composition of claim 108, wherein the poly(amidoamine) dendrimeric compound is a hydrophobe substituted poly(amidoamine) dendrimeric compound.

111. The conductive ink composition of claim 110, wherein the poly(amidoamine) dendrimeric compound is substituted with a C12 hydrophobe.

112. The conductive ink composition of claim 85, further comprising an acid stabilizer.

113. The conductive ink composition of claim 112, wherein the acid stabilizer is a C₆₋₁₂ α-branched alkanoic acid.

114. The conductive ink composition of claim 113, wherein the acid stabilizer is an α-branched decanoic acid isomer.

115. The conductive ink composition of claim 114, wherein the acid stabilizer is 2,2-dimethylhexanoic acid or 2,2-dimethylnonanoic acid.

116. The conductive ink composition of claim 85, wherein the silver decanoate comprises at least one α-branched silver decanoate isomer, the at least one dissolving agent comprises a limonene and a terpineol, and the adhesion promoter comprises a reactive silane and an epoxide.

117. The conductive ink composition of claim 116, further comprising an acid stabilizer.

118. The conductive ink composition of claim 85, wherein the silver decanoate comprises at least one α-branched silver decanoate isomer, the at least one dissolving agent comprises a limonene, and the conductive ink composition further comprises an acid stabilizer.

119. The conductive ink composition of claim 85, wherein the conductive ink composition has a concentration of about 1 to about 50 weight percent silver decanoate.

120. The conductive ink composition of claim 85, wherein the conductive ink composition has a viscosity from about 5 centipoise to about 50 centipoise.

121. The conductive ink composition of claim 85, wherein the conductive structure has a resistance of no more than 5 ohms per square, no more than 2 ohms per square, no more than 1 ohm per square, or no more than 0.5 ohms per square.

122. The conductive ink composition of claim 85, wherein the conductive structure has a bulk silver content of at least 1%.

123. The conductive ink composition of claim 85, wherein the silver decanoate is decarboxylated at a temperature of 180° C. or less to form the conductive structure.

124. The conductive ink composition of claim 85, wherein the silver decanoate is decarboxylated at a temperature of 150° C. or less to form the conductive structure.

125. A method of making a conductive ink composition, comprising:
dissolving a silver decanoate and an adhesion promoter in at least one dissolving agent to form a conductive ink composition;
wherein the silver decanoate comprises at least one α-branched silver decanoate isomer and wherein the adhesion promoter comprises a reactive silane or an epoxide or comprises a dendrimeric compound.

126. The method of claim 125, wherein the silver decanoate comprises a plurality of α-branched silver decanoate isomers.

127. The method of claim 125, wherein the silver decanoate has a structure: 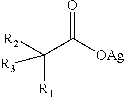
wherein R₁ and R₂ is each independently an alkyl group, wherein R₃ is either hydrogen or an alkyl group, and wherein R₁, R₂, and R₃ together comprise eight total carbon atoms.

128. The method of claim 127, wherein R₁ and R₂ is each independently methyl or ethyl.

129. The method of claim 127, wherein the silver decanoate comprises silver 2,2-dimethyloctanoate, silver 2,2,3,5-tetramethylhexanoate, silver 2,4-dimethyl-2-isopropylpentanoate, silver 2,5-dimethyl-2-ethylhexanoate, silver 2,2-diethylhexanoate, silver 2-butylhexanoate, or a combination thereof.

130. The method of claim 125, wherein the at least one dissolving agent comprises a terpene or a terpenoid.

131. The method of claim 130, wherein the terpene is a pinene or a limonene.

132. The method of claim 130, wherein the terpenoid is a terpineol.

133. The method of claim 130, wherein the at least one dissolving agent comprises a limonene or a terpineol.

134. The method of claim 133, wherein the limonene is a purified limonene and the terpineol is a purified terpineol.

135. The method of claim 125, wherein the adhesion promoter comprises a reactive silane and an epoxide.

136. The method of claim 135, wherein the adhesion promoter is a structure of formula I: 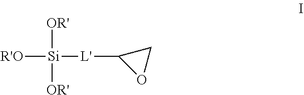
wherein each R′ is independently a C₁-C₆ alkyl group, and L′ is an alkyl linker group.

137. The method of claim 136, wherein each R′ is independently a methyl or an ethyl group.

138. The method of claim 136, wherein L′ is a C₂-C₁₀-alkyl linker group.

139. The method of claim 138, wherein L′ is a substituted C₂-C₁₀-alkyl linker group.

140. The method of claim 139, wherein one or more carbon atoms in L′ is be substituted with a heteroatom.

141. The method of claim 136, wherein the adhesion promoter is a structure of formula II: 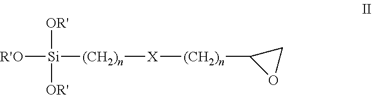
wherein each R′ is independently a methyl or an ethyl group, X is a heteroatom, and each n is independently 1-6.

142. The method of claim 141, wherein each R′ is a methyl group, X is oxygen, and each n is independently 1-3.

143. The method of claim 136, wherein the adhesion promoter is:

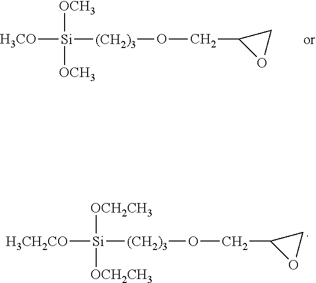

144. The method of claim 125, wherein the adhesion promoter comprises an alkoxysilane.

145. The method of claim 144, wherein the adhesion promoter comprises a methoxysilyl or an ethoxysilyl group.

146. The method of claim 125, wherein the adhesion promoter comprises a poly(amidoamine) dendrimeric compound.

147. The method of claim 146, wherein the poly(amidoamine) dendrimeric compound is a generation 2 poly(amidoamine) dendrimeric compound.

148. The method of claim 146, wherein the poly(amidoamine) dendrimeric compound is a hydrophobe substituted poly(amidoamine) dendrimeric compound.

149. The method of claim 148, wherein the poly(amidoamine) dendrimeric compound is substituted with a C12 hydrophobe.

150. The method of claim 125, comprising the further step of dissolving an acid stabilizer in the at least one dissolving agent.

151. The method of claim 150, wherein the acid stabilizer is a C₆₋₁₂ α-branched alkanoic acid.

152. The method of claim 151, wherein the acid stabilizer is an α-branched decanoic acid isomer.

153. The method of claim 152, wherein the acid stabilizer is 2,2-dimethylhexanoic acid or 2,2-dimethylnonanoic acid.

154. The method of claim 125, wherein the at least one dissolving agent comprises a limonene or a terpineol.

155. The method of claim 154, comprising the further step of dissolving an acid stabilizer in the at least one dissolving agent.

156. The method of claim 125, wherein the conductive ink composition has a concentration of about 1 to about 50 weight percent silver decanoate.

157. The method of claim 125, wherein the conductive ink composition has a viscosity from about 5 centipoise to about 50 centipoise.

158. The method of claim 125, wherein the silver decanoate is decarboxylated at a temperature of 180° C. or less to form a conductive structure.

159. The method of claim 125, wherein the silver decanoate is decarboxylated at a temperature of 150° C. or less to form a conductive structure.

160. A method of forming a conductive structure, comprising:
applying the conductive ink composition of any one of claims 85-124 to a substrate; and
heating the conductive ink composition on the substrate to a temperature of about 250° C. or less to form the conductive structure.

161. The method of claim 160, wherein the conductive ink composition is applied by slot die coating, spin coating, roll-to-roll printing, including gravure, flexography, rotary screen printing, screen printing, aerosol jet printing, inkjet printing, airbrushing, Mayer rod coating, flood coating, 3D printing, dispenser, or electrohydrodynamic printing.

162. The method of claim 160, wherein the conductive structure has a resistance of no more than 5 ohms per square, no more than 2 ohms per square, no more than 1 ohm per square, or no more than 0.5 ohms per square.

163. The method of claim 160, wherein the conductive structure has a bulk silver content of at least 1%.
